(19) United States
(12) Patent Application Publication
(10) Pub. No.: US 2026/0230220 A1
(43) Pub. Date: Aug. 6, 2026

(54) POLYNOMIAL APPROXIMATION TECHNIQUES FOR PROBABILISTIC AMPLITUDE SHAPING

(71) Applicant: QUALCOMM Incorporated, San Diego, CA (US)

(72) Inventors: Wei LIU, Beijing (CN); Thomas Joseph RICHARDSON, South Orange, NJ (US); Changlong XU, Beijing (CN); Hao XU, Beijing (CN)

(21) Appl. No.: 19/129,475

(22) PCT Filed: Feb. 1, 2023
(86) PCT No.: PCT/CN2023/074096

§ 371 Date: May 13, 2025

(51) Int. Cl. H04L 1/00

(52) U.S. Cl. CPC H04L 1/0042

(57) ABSTRACT

Various aspects of the present disclosure generally relate to wireless communication. In some aspects, a transmitter device may obtain a plurality of information bits. The transmitter device may form polynomial approximations of a plurality of approximation factors. The transmitter device may obtain, using the polynomial approximations of the plurality of approximation factors, an approximation of a logarithm of a cumulative sequence quantity. The transmitter device may perform an exponentiation operation on the approximation of the logarithm of the cumulative sequence quantity, thereby obtaining an approximation of the cumulative sequence quantity. The transmitter device may encode the plurality of information bits to obtain a symbol sequence based at least in part on the approximation of the cumulative sequence quantity. The transmitter device may transmit a message to one or more receiver devices based at least in part on the symbol sequence. Numerous other aspects are described.

### FIELD OF THE DISCLOSURE

Aspects of the present disclosure generally relate to wireless communication and to techniques and apparatuses for polynomial approximation techniques for probabilistic amplitude shaping.

### BACKGROUND

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power, or the like). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, time division synchronous code division multiple access (TD-SCDMA) systems, and Long Term Evolution (LTE). LTE/LTE-Advanced is a set of enhancements to the Universal Mobile Telecommunications System (UMTS) mobile standard promulgated by the Third Generation Partnership Project (3GPP).

A wireless network may include one or more network nodes that support communication for wireless communication devices, such as a user equipment (UE) or multiple UEs. A UE may communicate with a network node via downlink communications and uplink communications. “Downlink” (or “DL”) refers to a communication link from the network node to the UE, and “uplink” (or “UL”) refers to a communication link from the UE to the network node. Some wireless networks may support device-to-device communication, such as via a local link (e.g., a sidelink (SL), a wireless local area network (WLAN) link, and/or a wireless personal area network (WPAN) link, among other examples).

The above multiple access technologies have been adopted in various telecommunication standards to provide a common protocol that enables different UEs to communicate on a municipal, national, regional, and/or global level. New Radio (NR), which may be referred to as 5G, is a set of enhancements to the LTE mobile standard promulgated by the 3GPP. NR is designed to better support mobile broadband internet access by improving spectral efficiency, lowering costs, improving services, making use of new spectrum, and better integrating with other open standards using orthogonal frequency division multiplexing (OFDM) with a cyclic prefix (CP) (CP-OFDM) on the downlink, using CP-OFDM and/or single-carrier frequency division multiplexing (SC-FDM) (also known as discrete Fourier transform spread OFDM (DFT-s-OFDM)) on the uplink, as well as supporting beamforming, multiple-input multiple-output (MIMO) antenna technology, and carrier aggregation. As the demand for mobile broadband access continues to increase, further improvements in LTE, NR, and other radio access technologies remain useful.

### SUMMARY

In some implementations, an apparatus for wireless communication at a transmitter device includes a memory and one or more processors, coupled to the memory, configured to: obtain a plurality of information bits for a probabilistic shaping scheme, the probabilistic shaping scheme being associated with an energy threshold; form, as part of the probabilistic shaping scheme, polynomial approximations of a plurality of approximation factors; obtain, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy; perform an exponentiation operation on the approximation of the logarithm of the cumulative sequence quantity, thereby obtaining an approximation of the cumulative sequence quantity; encode, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size; and transmit a message to one or more receiver devices based at least in part on the symbol sequence.

In some implementations, a method of wireless communication performed by a transmitter device includes obtaining a plurality of information bits for a probabilistic shaping scheme, the probabilistic shaping scheme being associated with an energy threshold; forming, as part of the probabilistic shaping scheme, polynomial approximations of a plurality of approximation factors; obtaining, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy; performing an exponentiation operation on the approximation of the logarithm of the cumulative sequence quantity, thereby obtaining an approximation of the cumulative sequence quantity; encoding, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size; and transmitting a message to one or more receiver devices based at least in part on the symbol sequence.

In some implementations, a non-transitory computer-readable medium storing a set of instructions for wireless communication includes one or more instructions that, when executed by one or more processors of a transmitter device, cause the transmitter device to: obtain a plurality of information bits for a probabilistic shaping scheme, the probabilistic shaping scheme being associated with an energy threshold; form, as part of the probabilistic shaping scheme, polynomial approximations of a plurality of approximation factors; obtain, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy; perform an exponentiation operation on the approximation of the logarithm of the cumulative sequence quantity, thereby obtaining an approximation of the cumulative sequence quantity; encode, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size; and transmit a message to one or more receiver devices based at least in part on the symbol sequence.

In some implementations, an apparatus for wireless communication includes means for obtaining a plurality of information bits for a probabilistic shaping scheme, the probabilistic shaping scheme being associated with an energy threshold; means for forming, as part of the probabilistic shaping scheme, polynomial approximations of a plurality of approximation factors; means for obtaining, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy; means for performing an exponentiation operation on the approximation of the logarithm of the cumulative sequence quantity, thereby obtaining an approximation of the cumulative sequence quantity; means for encoding, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size; and means for transmitting a message to one or more receiver devices based at least in part on the symbol sequence.

Aspects generally include a method, apparatus, system, computer program product, non-transitory computer-readable medium, user equipment, base station, network entity, network node, transmitter device, wireless communication device, and/or processing system as substantially described herein with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages, will be better understood from the following description when considered in connection with the accompanying figures. Each of the figures is provided for the purposes of illustration and description, and not as a definition of the limits of the claims.

While aspects are described in the present disclosure by illustration to some examples, those skilled in the art will understand that such aspects may be implemented in many different arrangements and scenarios. Techniques described herein may be implemented using different platform types, devices, systems, shapes, sizes, and/or packaging arrangements. For example, some aspects may be implemented via integrated chip embodiments or other non-module-component based devices (e.g., end-user devices, vehicles, communication devices, computing devices, industrial equipment, retail/purchasing devices, medical devices, and/or artificial intelligence devices). Aspects may be implemented in chip-level components, modular components, non-modular components, non-chip-level components, device-level components, and/or system-level components. Devices incorporating described aspects and features may include additional components and features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, and/or summers). It is intended that aspects described herein may be practiced in a wide variety of devices, components, systems, distributed arrangements, and/or end-user devices of varying size, shape, and constitution.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example of a wireless network, in accordance with the present disclosure.

FIG. 2 is a diagram illustrating an example of a network node in communication with a user equipment (UE) in a wireless network, in accordance with the present disclosure.

FIG. 3 is a diagram illustrating an example disaggregated base station architecture, in accordance with the present disclosure.

FIG. 4 is a diagram illustrating an example of a transmitter chain, in accordance with the present disclosure.

FIG. 5 is a diagram illustrating an example of logarithm(s) of cumulative sequence quantities, in accordance with the present disclosure.

FIG. 6 is a diagram illustrating an example of absolute errors of approximation, in accordance with the present disclosure.

FIG. 7 is a diagram illustrating an example associated with polynomial approximation techniques for probabilistic amplitude shaping, in accordance with the present disclosure.

FIGS. 8A and 8B are diagrams illustrating an example 800 associated with absolute errors of approximation, in accordance with the present disclosure.

FIG. 9 is a diagram illustrating an example associated with approximation regions, in accordance with the present disclosure.

FIG. 10 is a diagram illustrating an example associated with approximation regions, in accordance with the present disclosure.

FIGS. 11A and 11B are diagrams illustrating examples associated with a first interval structure, in accordance with the present disclosure.

FIG. 12 is a diagram illustrating an example associated with a first additional interval structure, in accordance with the present disclosure.

FIG. 13 is a diagram illustrating an example associated with a second interval structure, in accordance with the present disclosure.

FIG. 14 is a diagram illustrating an example associated with a search, in accordance with the present disclosure.

FIG. 15 is a diagram illustrating an example associated with a look-up table for storage of polynomial coefficients, in accordance with the present disclosure.

FIG. 16 is a diagram illustrating an example process associated with polynomial approximation techniques for probabilistic amplitude shaping, in accordance with the present disclosure.

FIG. 17 is a diagram of an example apparatus for wireless communication, in accordance with the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Several aspects of telecommunication systems will now be presented with reference to various apparatuses and techniques. These apparatuses and techniques will be described in the following detailed description and illustrated in the accompanying drawings by various blocks, modules, components, circuits, steps, processes, algorithms, or the like (collectively referred to as “elements”). These elements may be implemented using hardware, software, or combinations thereof. Whether such elements are implemented as hardware or software depends upon the particular application and design constraints imposed on the overall system.

While aspects may be described herein using terminology commonly associated with a 5G or New Radio (NR) radio access technology (RAT), aspects of the present disclosure can be applied to other RATs, such as a 3G RAT, a 4G RAT, and/or a RAT subsequent to 5G (e.g., 6G).

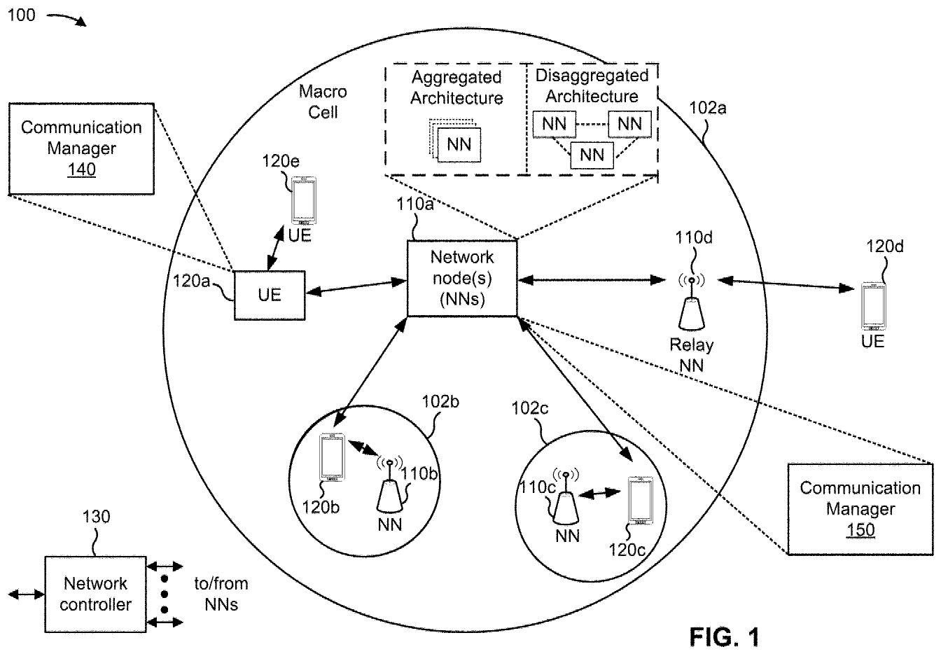

FIG. 1 is a diagram illustrating an example of a wireless network 100, in accordance with the present disclosure. The wireless network 100 may be or may include elements of a 5G (e.g., NR) network and/or a 4G (e.g., Long Term Evolution (LTE)) network, among other examples. The wireless network 100 may include one or more network nodes 110 (shown as a network node 110a, a network node 110b, a network node 110c, and a network node 110d), a user equipment (UE) 120 or multiple UEs 120 (shown as a UE 120a, a UE 120b, a UE 120c, a UE 120d, and a UE 120e), and/or other entities. A network node 110 is a network node that communicates with UEs 120. As shown, a network node 110 may include one or more network nodes. For example, a network node 110 may be an aggregated network node, meaning that the aggregated network node is configured to utilize a radio protocol stack that is physically or logically integrated within a single radio access network (RAN) node (e.g., within a single device or unit). As another example, a network node 110 may be a disaggregated network node (sometimes referred to as a disaggregated base station), meaning that the network node 110 is configured to utilize a protocol stack that is physically or logically distributed among two or more nodes (such as one or more central units (CUs), one or more distributed units (DUs), or one or more radio units (RUs)).

In some examples, a network node 110 is or includes a network node that communicates with UEs 120 via a radio access link, such as an RU. In some examples, a network node 110 is or includes a network node that communicates with other network nodes 110 via a fronthaul link or a midhaul link, such as a DU. In some examples, a network node 110 is or includes a network node that communicates with other network nodes 110 via a midhaul link or a core network via a backhaul link, such as a CU. In some examples, a network node 110 (such as an aggregated network node 110 or a disaggregated network node 110) may include multiple network nodes, such as one or more RUs, one or more CUs, and/or one or more DUs. A network node 110 may include, for example, an NR base station, an LTE base station, a Node B, an eNB (e.g., in 4G), a gNB (e.g., in 5G), an access point, a transmission reception point (TRP), a DU, an RU, a CU, a mobility element of a network, a core network node, a network element, a network equipment, a RAN node, or a combination thereof. In some examples, the network nodes 110 may be interconnected to one another or to one or more other network nodes 110 in the wireless network 100 through various types of fronthaul, midhaul, and/or backhaul interfaces, such as a direct physical connection, an air interface, or a virtual network, using any suitable transport network.

In some examples, a network node 110 may provide communication coverage for a particular geographic area. In the Third Generation Partnership Project (3GPP), the term “cell” can refer to a coverage area of a network node 110 and/or a network node subsystem serving this coverage area, depending on the context in which the term is used. A network node 110 may provide communication coverage for a macro cell, a pico cell, a femto cell, and/or another type of cell. A macro cell may cover a relatively large geographic area (e.g., several kilometers in radius) and may allow unrestricted access by UEs 120 with service subscriptions. A pico cell may cover a relatively small geographic area and may allow unrestricted access by UEs 120 with service subscriptions. A femto cell may cover a relatively small geographic area (e.g., a home) and may allow restricted access by UEs 120 having association with the femto cell (e.g., UEs 120 in a closed subscriber group (CSG)). A network node 110 for a macro cell may be referred to as a macro network node. A network node 110 for a pico cell may be referred to as a pico network node. A network node 110 for a femto cell may be referred to as a femto network node or an in-home network node. In the example shown in FIG. 1, the network node 110a may be a macro network node for a macro cell 102a, the network node 110b may be a pico network node for a pico cell 102b, and the network node 110c may be a femto network node for a femto cell 102c. A network node may support one or multiple (e.g., three) cells. In some examples, a cell may not necessarily be stationary, and the geographic area of the cell may move according to the location of a network node 110 that is mobile (e.g., a mobile network node).

In some aspects, the terms “base station” or “network node” may refer to an aggregated base station, a disaggregated base station, an integrated access and backhaul (IAB) node, a relay node, or one or more components thereof. For example, in some aspects, “base station” or “network node” may refer to a CU, a DU, an RU, a Near-Real Time (Near-RT) RAN Intelligent Controller (RIC), or a Non-Real Time (Non-RT) RIC, or a combination thereof. In some aspects, the terms “base station” or “network node” may refer to one device configured to perform one or more functions, such as those described herein in connection with the network node 110. In some aspects, the terms “base station” or “network node” may refer to a plurality of devices configured to perform the one or more functions. For example, in some distributed systems, each of a quantity of different devices (which may be located in the same geographic location or in different geographic locations) may be configured to perform at least a portion of a function, or to duplicate performance of at least a portion of the function, and the terms “base station” or “network node” may refer to any one or more of those different devices. In some aspects, the terms “base station” or “network node” may refer to one or more virtual base stations or one or more virtual base station functions. For example, in some aspects, two or more base station functions may be instantiated on a single device. In some aspects, the terms “base station” or “network node” may refer to one of the base station functions and not another. In this way, a single device may include more than one base station.

The wireless network 100 may include one or more relay stations. A relay station is a network node that can receive a transmission of data from an upstream node (e.g., a network node 110 or a UE 120) and send a transmission of the data to a downstream node (e.g., a UE 120 or a network node 110). A relay station may be a UE 120 that can relay transmissions for other UEs 120. In the example shown in FIG. 1, the network node 110d (e.g., a relay network node) may communicate with the network node 110a (e.g., a macro network node) and the UE 120d in order to facilitate communication between the network node 110a and the UE 120d. A network node 110 that relays communications may be referred to as a relay station, a relay base station, a relay network node, a relay node, a relay, or the like.

The wireless network 100 may be a heterogeneous network that includes network nodes 110 of different types, such as macro network nodes, pico network nodes, femto network nodes, relay network nodes, or the like. These different types of network nodes 110 may have different transmit power levels, different coverage areas, and/or different impacts on interference in the wireless network 100. For example, macro network nodes may have a high transmit power level (e.g., 5 to 40 watts) whereas pico network nodes, femto network nodes, and relay network nodes may have lower transmit power levels (e.g., 0.1 to 2 watts).

A network controller 130 may couple to or communicate with a set of network nodes 110 and may provide coordination and control for these network nodes 110. The network controller 130 may communicate with the network nodes 110 via a backhaul communication link or a midhaul communication link. The network nodes 110 may communicate with one another directly or indirectly via a wireless or wireline backhaul communication link. In some aspects, the network controller 130 may be a CU or a core network device, or may include a CU or a core network device.

The UEs 120 may be dispersed throughout the wireless network 100, and each UE 120 may be stationary or mobile. A UE 120 may include, for example, an access terminal, a terminal, a mobile station, and/or a subscriber unit. A UE 120 may be a cellular phone (e.g., a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device, a biometric device, a wearable device (e.g., a smart watch, smart clothing, smart glasses, a smart wristband, smart jewelry (e.g., a smart ring or a smart bracelet)), an entertainment device (e.g., a music device, a video device, and/or a satellite radio), a vehicular component or sensor, a smart meter/sensor, industrial manufacturing equipment, a global positioning system device, a UE function of a network node, and/or any other suitable device that is configured to communicate via a wireless or wired medium.

Some UEs 120 may be considered machine-type communication (MTC) or evolved or enhanced machine-type communication (eMTC) UEs. An MTC UE and/or an eMTC UE may include, for example, a robot, a drone, a remote device, a sensor, a meter, a monitor, and/or a location tag, that may communicate with a network node, another device (e.g., a remote device), or some other entity. Some UEs 120 may be considered Internet-of-Things (IoT) devices, and/or may be implemented as NB-IoT (narrowband IoT) devices. Some UEs 120 may be considered a Customer Premises Equipment. A UE 120 may be included inside a housing that houses components of the UE 120, such as processor components and/or memory components. In some examples, the processor components and the memory components may be coupled together. For example, the processor components (e.g., one or more processors) and the memory components (e.g., a memory) may be operatively coupled, communicatively coupled, electronically coupled, and/or electrically coupled.

In general, any number of wireless networks 100 may be deployed in a given geographic area. Each wireless network 100 may support a particular RAT and may operate on one or more frequencies. A RAT may be referred to as a radio technology, an air interface, or the like. A frequency may be referred to as a carrier, a frequency channel, or the like. Each frequency may support a single RAT in a given geographic area in order to avoid interference between wireless networks of different RATs. In some cases, NR or 5G RAT networks may be deployed.

In some examples, two or more UEs 120 (e.g., shown as UE 120a and UE 120e) may communicate directly using one or more sidelink channels (e.g., without using a network node 110 as an intermediary to communicate with one another). For example, the UEs 120 may communicate using peer-to-peer (P2P) communications, device-to-device (D2D) communications, a vehicle-to-everything (V2X) protocol (e.g., which may include a vehicle-to-vehicle (V2V) protocol, a vehicle-to-infrastructure (V2I) protocol, or a vehicle-to-pedestrian (V2P) protocol), and/or a mesh network. In such examples, a UE 120 may perform scheduling operations, resource selection operations, and/or other operations described elsewhere herein as being performed by the network node 110.

Devices of the wireless network 100 may communicate using the electromagnetic spectrum, which may be subdivided by frequency or wavelength into various classes, bands, channels, or the like. For example, devices of the wireless network 100 may communicate using one or more operating bands. In 5G NR, two initial operating bands have been identified as frequency range designations FR1 (410 MHz-7.125 GHz) and FR2 (24.25 GHz-52.6 GHz). It should be understood that although a portion of FR1 is greater than 6 GHz, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHz-24.25 GHz). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR4a or FR4-1 (52.6 GHz-71 GHz), FR4 (52.6 GHz-114.25 GHz), and FR5 (114.25 GHz-300 GHz). Each of these higher frequency bands falls within the EHF band.

With the above examples in mind, unless specifically stated otherwise, it should be understood that the term “sub-6 GHz” or the like, if used herein, may broadly represent frequencies that may be less than 6 GHz, may be within FR1, or may include mid-band frequencies. Further, unless specifically stated otherwise, it should be understood that the term “millimeter wave” or the like, if used herein, may broadly represent frequencies that may include mid-band frequencies, may be within FR2, FR4, FR4-a or FR4-1, and/or FR5, or may be within the EHF band. It is contemplated that the frequencies included in these operating bands (e.g., FR1, FR2, FR3, FR4, FR4-a, FR4-1, and/or FR5) may be modified, and techniques described herein are applicable to those modified frequency ranges.

In some aspects, a transmitter device (e.g., UE 120 or network node 110) may include a communication manager 140 or a communication manager 150. As described in more detail elsewhere herein, the communication manager 140 or the communication manager 150 may obtain a plurality of information bits for a probabilistic shaping scheme, the probabilistic shaping scheme being associated with an energy threshold; form, as part of the probabilistic shaping scheme, polynomial approximations of a plurality of approximation factors; obtain, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy; perform an exponentiation operation on the approximation of the logarithm of the cumulative sequence quantity, thereby obtaining an approximation of the cumulative sequence quantity; encode, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size; and transmit a message to one or more receiver devices based at least in part on the symbol sequence. Additionally, or alternatively, the communication manager 140 or the communication manager 150 may perform one or more other operations described herein.

As indicated above, FIG. 1 is provided as an example. Other examples may differ from what is described with regard to FIG. 1.

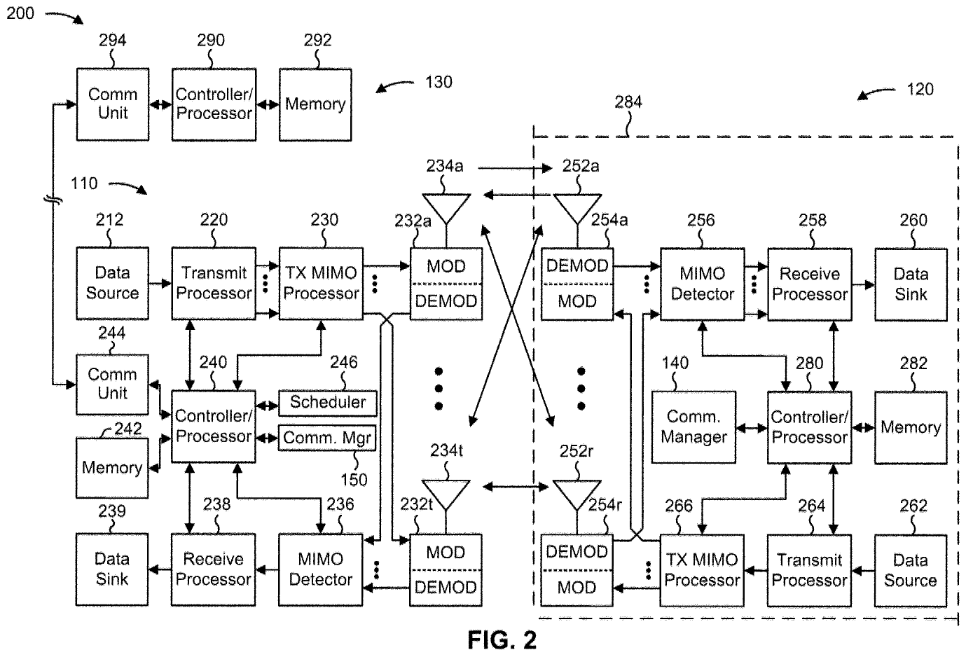

FIG. 2 is a diagram illustrating an example 200 of a network node 110 in communication with a UE 120 in a wireless network 100, in accordance with the present disclosure. The network node 110 may be equipped with a set of antennas 234a through 234t, such as T antennas (T≥1). The UE 120 may be equipped with a set of antennas 252a through 252r, such as R antennas (R≥1). The network node 110 of example 200 includes one or more radio frequency components, such as antennas 234 and a modem 232. In some examples, a network node 110 may include an interface, a communication component, or another component that facilitates communication with the UE 120 or another network node. Some network nodes 110 may not include radio frequency components that facilitate direct communication with the UE 120, such as one or more CUs, or one or more DUs.

At the network node 110, a transmit processor 220 may receive data, from a data source 212, intended for the UE 120 (or a set of UEs 120). The transmit processor 220 may select one or more modulation and coding schemes (MCSs) for the UE 120 based at least in part on one or more channel quality indicators (CQIs) received from that UE 120. The network node 110 may process (e.g., encode and modulate) the data for the UE 120 based at least in part on the MCS(s) selected for the UE 120 and may provide data symbols for the UE 120. The transmit processor 220 may process system information (e.g., for semi-static resource partitioning information (SRPI)) and control information (e.g., CQI requests, grants, and/or upper layer signaling) and provide overhead symbols and control symbols. The transmit processor 220 may generate reference symbols for reference signals (e.g., a cell-specific reference signal (CRS) or a demodulation reference signal (DMRS)) and synchronization signals (e.g., a primary synchronization signal (PSS) or a secondary synchronization signal (SSS)). A transmit (TX) multiple-input multiple-output (MIMO) processor 230 may perform spatial processing (e.g., precoding) on the data symbols, the control symbols, the overhead symbols, and/or the reference symbols, if applicable, and may provide a set of output symbol streams (e.g., T output symbol streams) to a corresponding set of modems 232 (e.g., T modems), shown as modems 232a through 232t. For example, each output symbol stream may be provided to a modulator component (shown as MOD) of a modem 232. Each modem 232 may use a respective modulator component to process a respective output symbol stream (e.g., for OFDM) to obtain an output sample stream. Each modem 232 may further use a respective modulator component to process (e.g., convert to analog, amplify, filter, and/or upconvert) the output sample stream to obtain a downlink signal. The modems 232a through 232t may transmit a set of downlink signals (e.g., T downlink signals) via a corresponding set of antennas 234 (e.g., T antennas), shown as antennas 234a through 234t.

At the UE 120, a set of antennas 252 (shown as antennas 252a through 252r) may receive the downlink signals from the network node 110 and/or other network nodes 110 and may provide a set of received signals (e.g., R received signals) to a set of modems 254 (e.g., R modems), shown as modems 254a through 254r. For example, each received signal may be provided to a demodulator component (shown as DEMOD) of a modem 254. Each modem 254 may use a respective demodulator component to condition (e.g., filter, amplify, downconvert, and/or digitize) a received signal to obtain input samples. Each modem 254 may use a demodulator component to further process the input samples (e.g., for OFDM) to obtain received symbols. A MIMO detector 256 may obtain received symbols from the modems 254, may perform MIMO detection on the received symbols if applicable, and may provide detected symbols. A receive processor 258 may process (e.g., demodulate and decode) the detected symbols, may provide decoded data for the UE 120 to a data sink 260, and may provide decoded control information and system information to a controller/processor 280. The term “controller/processor” may refer to one or more controllers, one or more processors, or a combination thereof. A channel processor may determine a reference signal received power (RSRP) parameter, a received signal strength indicator (RSSI) parameter, a reference signal received quality (RSRQ) parameter, and/or a CQI parameter, among other examples. In some examples, one or more components of the UE 120 may be included in a housing 284.

The network controller 130 may include a communication unit 294, a controller/processor 290, and a memory 292. The network controller 130 may include, for example, one or more devices in a core network. The network controller 130 may communicate with the network node 110 via the communication unit 294.

One or more antennas (e.g., antennas 234a through 234t and/or antennas 252a through 252r) may include, or may be included within, one or more antenna panels, one or more antenna groups, one or more sets of antenna elements, and/or one or more antenna arrays, among other examples. An antenna panel, an antenna group, a set of antenna elements, and/or an antenna array may include one or more antenna elements (within a single housing or multiple housings), a set of coplanar antenna elements, a set of non-coplanar antenna elements, and/or one or more antenna elements coupled to one or more transmission and/or reception components, such as one or more components of FIG. 2.

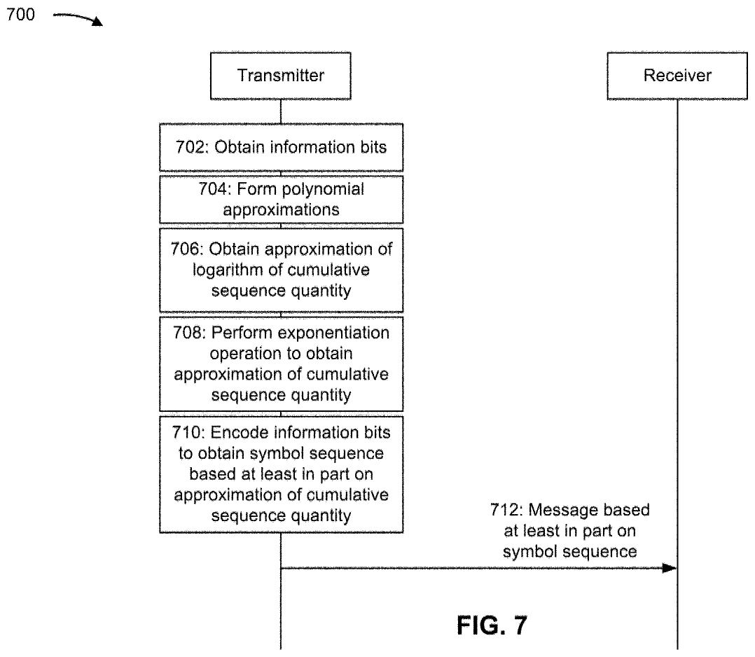

On the uplink, at the UE 120, a transmit processor 264 may receive and process data from a data source 262 and control information (e.g., for reports that include RSRP, RSSI, RSRQ, and/or CQI) from the controller/processor 280. The transmit processor 264 may generate reference symbols for one or more reference signals. The symbols from the transmit processor 264 may be precoded by a TX MIMO processor 266 if applicable, further processed by the modems 254 (e.g., for DFT-s-OFDM or CP-OFDM), and transmitted to the network node 110. In some examples, the modem 254 of the UE 120 may include a modulator and a demodulator. In some examples, the UE 120 includes a transceiver. The transceiver may include any combination of the antenna(s) 252, the modem(s) 254, the MIMO detector 256, the receive processor 258, the transmit processor 264, and/or the TX MIMO processor 266. The transceiver may be used by a processor (e.g., the controller/processor 280) and the memory 282 to perform aspects of any of the methods described herein (e.g., with reference to FIGS. 7-17).

At the network node 110, the uplink signals from UE 120 and/or other UEs may be received by the antennas 234, processed by the modem 232 (e.g., a demodulator component, shown as DEMOD, of the modem 232), detected by a MIMO detector 236 if applicable, and further processed by a receive processor 238 to obtain decoded data and control information sent by the UE 120. The receive processor 238 may provide the decoded data to a data sink 239 and provide the decoded control information to the controller/processor 240. The network node 110 may include a communication unit 244 and may communicate with the network controller 130 via the communication unit 244. The network node 110 may include a scheduler 246 to schedule one or more UEs 120 for downlink and/or uplink communications. In some examples, the modem 232 of the network node 110 may include a modulator and a demodulator. In some examples, the network node 110 includes a transceiver. The transceiver may include any combination of the antenna(s) 234, the modem(s) 232, the MIMO detector 236, the receive processor 238, the transmit processor 220, and/or the TX MIMO processor 230. The transceiver may be used by a processor (e.g., the controller/processor 240) and the memory 242 to perform aspects of any of the methods described herein (e.g., with reference to FIGS. 7-17).

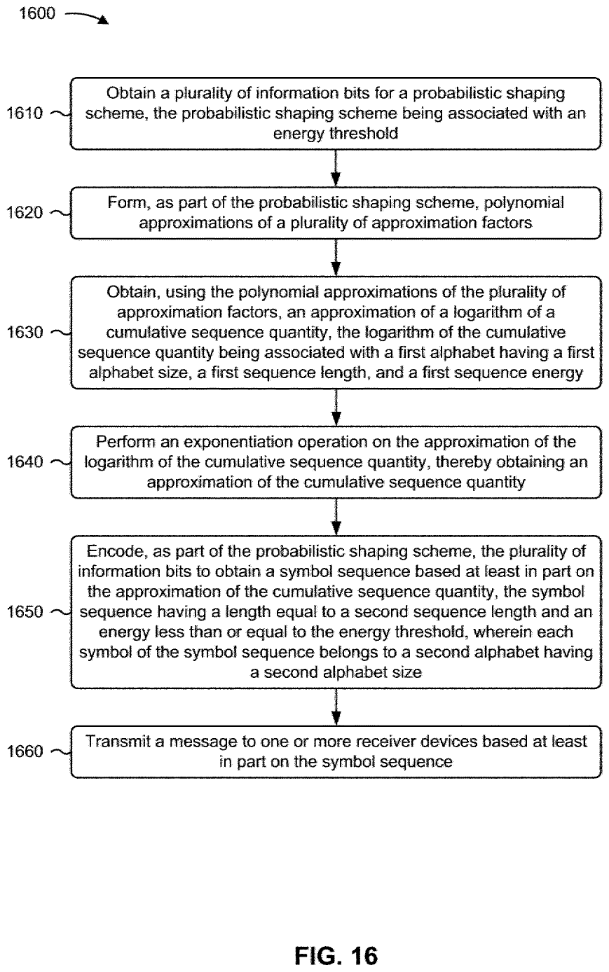

The controller/processor 240 of the network node 110, the controller/processor 280 of the UE 120, and/or any other component(s) of FIG. 2 may perform one or more techniques associated with polynomial approximation techniques for probabilistic amplitude shaping, as described in more detail elsewhere herein. In some aspects, the transmitter device described herein is the network node 110, is included in the network node 110, or includes one or more components of the network node 110 shown in FIG. 2. In some aspects, the transmitter device described herein is the UE 120, is included in the UE 120, or includes one or more components of the UE 120 shown in FIG. 2. For example, the controller/processor 240 of the network node 110, the controller/processor 280 of the UE 120, and/or any other component(s) of FIG. 2 may perform or direct operations of, for example, process 1600 of FIG. 16, and/or other processes as described herein. The memory 242 and the memory 282 may store data and program codes for the network node 110 and the UE 120, respectively. In some examples, the memory 242 and/or the memory 282 may include a non-transitory computer-readable medium storing one or more instructions (e.g., code and/or program code) for wireless communication. For example, the one or more instructions, when executed (e.g., directly, or after compiling, converting, and/or interpreting) by one or more processors of the network node 110 and/or the UE 120, may cause the one or more processors, the UE 120, and/or the network node 110 to perform or direct operations of, for example, process 1600 of FIG. 16, and/or other processes as described herein. In some examples, executing instructions may include running the instructions, converting the instructions, compiling the instructions, and/or interpreting the instructions, among other examples.

In some aspects, a transmitter device (e.g., UE 120 or network node 110) includes means for obtaining a plurality of information bits for a probabilistic shaping scheme, the probabilistic shaping scheme being associated with an energy threshold; means for forming, as part of the probabilistic shaping scheme, polynomial approximations of a plurality of approximation factors; means for obtaining, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy; means for performing an exponentiation operation on the approximation of the logarithm of the cumulative sequence quantity, thereby obtaining an approximation of the cumulative sequence quantity; means for encoding, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size; and/or means for transmitting a message to one or more receiver devices based at least in part on the symbol sequence. In some aspects, the means for the transmitter device to perform operations described herein may include, for example, one or more of communication manager 150, transmit processor 220, TX MIMO processor 230, modem 232, antenna 234, MIMO detector 236, receive processor 238, controller/processor 240, memory 242, or scheduler 246. In some aspects, the means for the transmitter device to perform operations described herein may include, for example, one or more of communication manager 140, antenna 252, modem 254, MIMO detector 256, receive processor 258, transmit processor 264, TX MIMO processor 266, controller/processor 280, or memory 282.

While blocks in FIG. 2 are illustrated as distinct components, the functions described above with respect to the blocks may be implemented in a single hardware, software, or combination component or in various combinations of components. For example, the functions described with respect to the transmit processor 264, the receive processor 258, and/or the TX MIMO processor 266 may be performed by or under the control of the controller/processor 280.

As indicated above, FIG. 2 is provided as an example. Other examples may differ from what is described with regard to FIG. 2.

Deployment of communication systems, such as 5G NR systems, may be arranged in multiple manners with various components or constituent parts. In a 5G NR system, or network, a network node, a network entity, a mobility element of a network, a RAN node, a core network node, a network element, a base station, or a network equipment may be implemented in an aggregated or disaggregated architecture. For example, a base station (such as a Node B (NB), an evolved NB (eNB), an NR base station, a 5G NB, an access point (AP), a TRP, or a cell, among other examples), or one or more units (or one or more components) performing base station functionality, may be implemented as an aggregated base station (also known as a standalone base station or a monolithic base station) or a disaggregated base station. “Network entity” or “network node” may refer to a disaggregated base station, or to one or more units of a disaggregated base station (such as one or more CUs, one or more DUs, one or more RUs, or a combination thereof).

An aggregated base station (e.g., an aggregated network node) may be configured to utilize a radio protocol stack that is physically or logically integrated within a single RAN node (e.g., within a single device or unit). A disaggregated base station (e.g., a disaggregated network node) may be configured to utilize a protocol stack that is physically or logically distributed among two or more units (such as one or more CUs, one or more DUs, or one or more RUs). In some examples, a CU may be implemented within a network node, and one or more DUs may be co-located with the CU, or alternatively, may be geographically or virtually distributed throughout one or multiple other network nodes. The DUs may be implemented to communicate with one or more RUs. Each of the CU, DU, and RU also can be implemented as virtual units, such as a virtual central unit (VCU), a virtual distributed unit (VDU), or a virtual radio unit (VRU), among other examples.

Base station-type operation or network design may consider aggregation characteristics of base station functionality. For example, disaggregated base stations may be utilized in an IAB network, an open radio access network (O-RAN (such as the network configuration sponsored by the O-RAN Alliance)), or a virtualized radio access network (vRAN, also known as a cloud radio access network (C-RAN)) to facilitate scaling of communication systems by separating base station functionality into one or more units that can be individually deployed. A disaggregated base station may include functionality implemented across two or more units at various physical locations, as well as functionality implemented for at least one unit virtually, which can enable flexibility in network design. The various units of the disaggregated base station can be configured for wired or wireless communication with at least one other unit of the disaggregated base station.

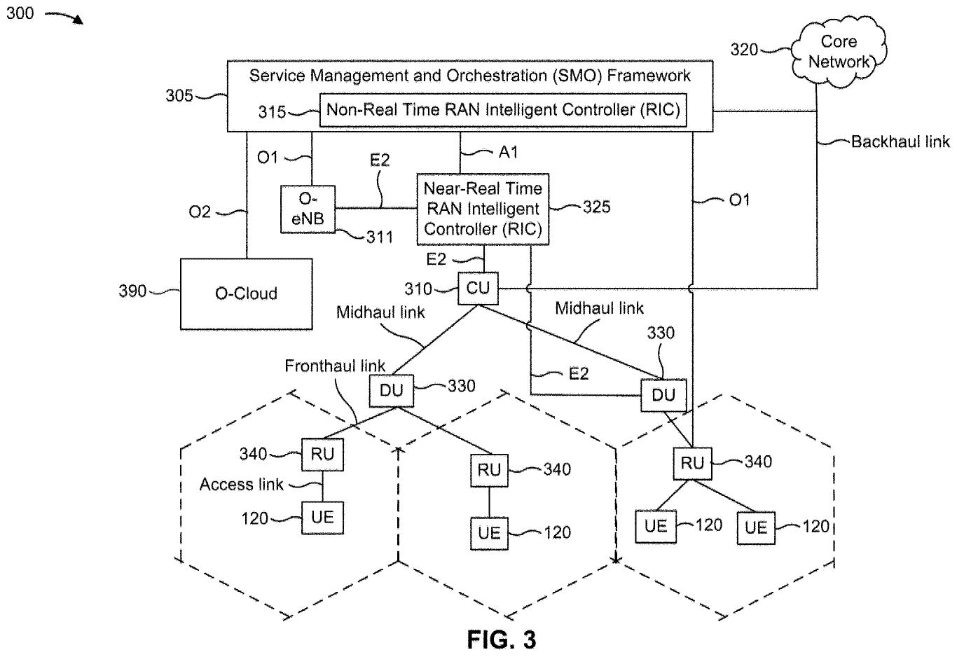

FIG. 3 is a diagram illustrating an example disaggregated base station architecture 300, in accordance with the present disclosure. The disaggregated base station architecture 300 may include a CU 310 that can communicate directly with a core network 320 via a backhaul link, or indirectly with the core network 320 through one or more disaggregated control units (such as a Near-RT RIC 325 via an E2 link, or a Non-RT RIC 315 associated with a Service Management and Orchestration (SMO) Framework 305, or both). A CU 310 may communicate with one or more DUs 330 via respective midhaul links, such as through F1 interfaces. Each of the DUs 330 may communicate with one or more RUs 340 via respective fronthaul links. Each of the RUs 340 may communicate with one or more UEs 120 via respective radio frequency (RF) access links. In some implementations, a UE 120 may be simultaneously served by multiple RUs 340.

Each of the units, including the CUs 310, the DUs 330, the RUs 340, as well as the Near-RT RICs 325, the Non-RT RICs 315, and the SMO Framework 305, may include one or more interfaces or be coupled with one or more interfaces configured to receive or transmit signals, data, or information (collectively, signals) via a wired or wireless transmission medium. Each of the units, or an associated processor or controller providing instructions to one or multiple communication interfaces of the respective unit, can be configured to communicate with one or more of the other units via the transmission medium. In some examples, each of the units can include a wired interface, configured to receive or transmit signals over a wired transmission medium to one or more of the other units, and a wireless interface, which may include a receiver, a transmitter or transceiver (such as an RF transceiver), configured to receive or transmit signals, or both, over a wireless transmission medium to one or more of the other units.

In some aspects, the CU 310 may host one or more higher layer control functions. Such control functions can include radio resource control (RRC) functions, packet data convergence protocol (PDCP) functions, or service data adaptation protocol (SDAP) functions, among other examples. Each control function can be implemented with an interface configured to communicate signals with other control functions hosted by the CU 310. The CU 310 may be configured to handle user plane functionality (for example, Central Unit-User Plane (CU-UP) functionality), control plane functionality (for example, Central Unit-Control Plane (CU-CP) functionality), or a combination thereof. In some implementations, the CU 310 can be logically split into one or more CU-UP units and one or more CU-CP units. A CU-UP unit can communicate bidirectionally with a CU-CP unit via an interface, such as the E1 interface when implemented in an O-RAN configuration. The CU 310 can be implemented to communicate with a DU 330, as necessary, for network control and signaling.

Each DU 330 may correspond to a logical unit that includes one or more base station functions to control the operation of one or more RUs 340. In some aspects, the DU 330 may host one or more of a radio link control (RLC) layer, a medium access control (MAC) layer, and one or more high physical (PHY) layers depending, at least in part, on a functional split, such as a functional split defined by the 3GPP. In some aspects, the one or more high PHY layers may be implemented by one or more modules for forward error correction (FEC) encoding and decoding, scrambling, and modulation and demodulation, among other examples. In some aspects, the DU 330 may further host one or more low PHY layers, such as implemented by one or more modules for a fast Fourier transform (FFT), an inverse FFT (iFFT), digital beamforming, or physical random access channel (PRACH) extraction and filtering, among other examples. Each layer (which also may be referred to as a module) can be implemented with an interface configured to communicate signals with other layers (and modules) hosted by the DU 330, or with the control functions hosted by the CU 310.

Each RU 340 may implement lower-layer functionality. In some deployments, an RU 340, controlled by a DU 330, may correspond to a logical node that hosts RF processing functions or low-PHY layer functions, such as performing an FFT, performing an iFFT, digital beamforming, or PRACH extraction and filtering, among other examples, based on a functional split (for example, a functional split defined by the 3GPP), such as a lower layer functional split. In such an architecture, each RU 340 can be operated to handle over the air (OTA) communication with one or more UEs 120. In some implementations, real-time and non-real-time aspects of control and user plane communication with the RU(s) 340 can be controlled by the corresponding DU 330. In some scenarios, this configuration can enable each DU 330 and the CU 310 to be implemented in a cloud-based RAN architecture, such as a vRAN architecture.

The SMO Framework 305 may be configured to support RAN deployment and provisioning of non-virtualized and virtualized network elements. For non-virtualized network elements, the SMO Framework 305 may be configured to support the deployment of dedicated physical resources for RAN coverage requirements, which may be managed via an operations and maintenance interface (such as an O1 interface). For virtualized network elements, the SMO Framework 305 may be configured to interact with a cloud computing platform (such as an open cloud (O-Cloud) platform 390) to perform network element life cycle management (such as to instantiate virtualized network elements) via a cloud computing platform interface (such as an O2 interface). Such virtualized network elements can include, but are not limited to, CUs 310, DUs 330, RUs 340, non-RT RICs 315, and Near-RT RICs 325. In some implementations, the SMO Framework 305 can communicate with a hardware aspect of a 4G RAN, such as an open eNB (O-eNB) 311, via an O1 interface. Additionally, in some implementations, the SMO Framework 305 can communicate directly with each of one or more RUs 340 via a respective O1 interface. The SMO Framework 305 also may include a Non-RT RIC 315 configured to support functionality of the SMO Framework 305.

The Non-RT RIC 315 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 325. The Non-RT RIC 315 may be coupled to or communicate with (such as via an A1 interface) the Near-RT RIC 325. The Near-RT RIC 325 may be configured to include a logical function that enables near-real-time control and optimization of RAN elements and resources via data collection and actions over an interface (such as via an E2 interface) connecting one or more CUs 310, one or more DUs 330, or both, as well as an O-eNB, with the Near-RT RIC 325.

In some implementations, to generate AI/ML models to be deployed in the Near-RT RIC 325, the Non-RT RIC 315 may receive parameters or external enrichment information from external servers. Such information may be utilized by the Near-RT RIC 325 and may be received at the SMO Framework 305 or the Non-RT RIC 315 from non-network data sources or from network functions. In some examples, the Non-RT RIC 315 or the Near-RT RIC 325 may be configured to tune RAN behavior or performance. For example, the Non-RT RIC 315 may monitor long-term trends and patterns for performance and employ AI/ML models to perform corrective actions through the SMO Framework 305 (such as reconfiguration via an O1 interface) or via creation of RAN management policies (such as A1 interface policies).

As indicated above, FIG. 3 is provided as an example. Other examples may differ from what is described with regard to FIG. 3.

In a wireless network, a transmitting node may encode information according to a certain forward-error-correction (FEC) coding scheme to improve transmission reliability. The transmitting node may then modulate the encoded information according to a certain modulation scheme for transmission. A modulation scheme may have a certain constellation with certain constellation points, which may also be referred to as modulation symbols. A transmission using a modulation scheme may carry information represented by modulation symbols from a certain set of constellation points defined for the modulation scheme.

Traditional signal constellations, such as amplitude shift keying (ASK) and quadrature amplitude modulation (QAM), are characterized by constellation points with equal distance and each constellation point is transmitted with the same probability. Unfortunately, such constellations result in a gap to the Shannon limit. To close this gap and to increase the spectral efficiency, constellation shaping may be applied. For an additive white Gaussian noise (AWGN) channel, constellation shaping may offer gains (termed shaping gain) up to 1.53 decibel (dB) in signal-to-noise ratio (SNR) by utilizing Gaussian shaped constellations.

A favorable performance with data rate close to the channel capacity may be achieved by a constellation with a Gaussian-like distribution. Geometric constellation shaping (GCS) and probabilistic amplitude shaping (PAS) are particular examples to provide non-uniform distribution of constellation using QAM. For GCS, each constellation point may be used with equal probability, while the location of the constellation points has an unequal distance and is arranged to mimic the capacity-achieving distribution. For PAS, or more generally, probabilistic constellation shaping (PCS), a constellation may be used, e.g., ASK or QAM, with constellation points having equal distance, and different probabilities may be assigned to different constellation points.

A transmitter chain in a transmitter device may be associated with an energy-based PAS architecture. The transmitter chain may consider ASK constellations with modulation order 2^{M}. An ASK constellation may consist of constellation points in {±1, ±3, . . . , ±(2^{M}−1)} with amplitude alphabet {1, 3, . . . , 2^{M}−1}. The energy-based PAS architecture may be generalized naturally to QAM constellations with modulation order 2^{2M}. A QAM constellation may consist of constellation points in {±1, ±3, . . . , ±(2^{M}−1)}×{±1, ±3, . . . , ±(2^{M}−1)} with amplitude alphabet {1, 3, . . . , 2^{M}−1}. In an energy-based probabilistic shaping, an energy of s^{n̅} may be constrained to be below an energy threshold Ē. The energy threshold E may refer to a maximum sequence energy. A target non-uniform distribution over the amplitude symbols may be induced by properly selecting the energy threshold Ē.

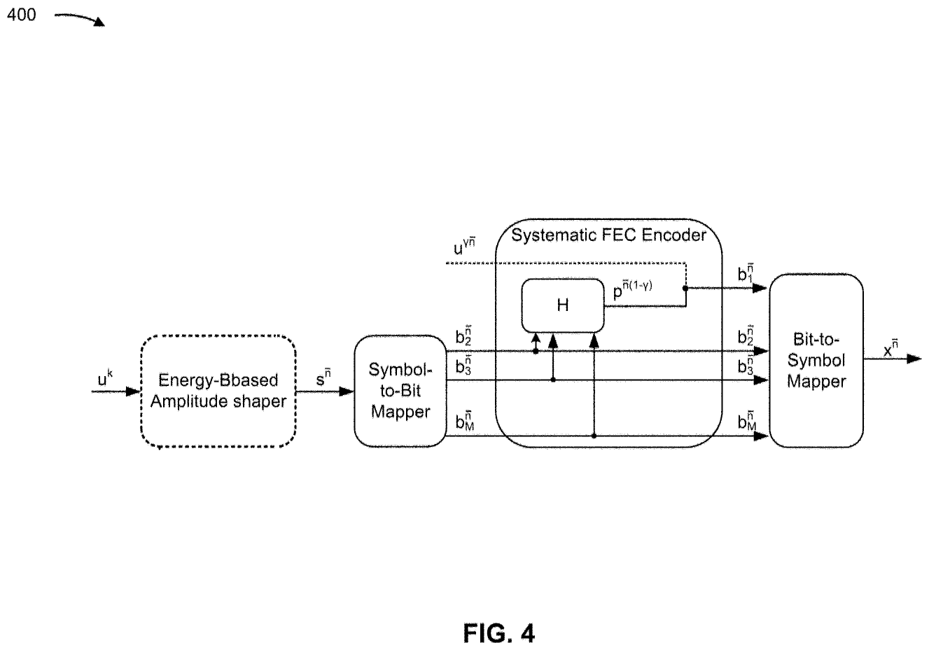

FIG. 4 is a diagram illustrating an example 400 of a transmitter chain, in accordance with the present disclosure.

As shown in FIG. 4, a transmitter chain in a transmitter device may include an energy-based amplitude shaper. An input to the energy-based amplitude shaper may be u^{k}, and an output of the energy-based amplitude shaper may be s^{n̅}. A symbol-to-bit mapper may receive the output of the energy-based amplitude shaper. The symbol-to-bit mapper may be coupled to a systematic FEC encoder, which may be coupled to a bit-to-symbol mapper. An output of the bit-to-symbol mapper may be x^{n̅}.

As indicated above, FIG. 4 is provided as an example. Other examples may differ from what is described with regard to FIG. 4.

In a transmitter chain of a transmitter device, an amplitude shaper with rate Rₐₛ=k/n̅ may encode k information bits to n amplitude symbols. The sequence u^{k}=(u₁, u₂, . . . , uₖ) may comprise the k information bits. The sequence s^{n̅}=(s₁, s₂, . . . , s_{n̅}) may comprise the n̅ amplitude symbols. The non-uniform symbol-wise marginal distribution over the n̅ amplitude symbols induced by the energy-based amplitude shaper may be closer to the capacity-achieving input distribution than the uniform distribution. For example, the non-uniform distribution may be a Maxwell-Boltzmann (MB) distribution for the AWGN channel. The sequence s^{n̅} may be converted to (M−1) bit sequences of length n̅ denoted by

$${b}_{2}^{\overline{n}} , {b}_{3}^{\overline{n}} , … , {b}_{M}^{\overline{n}} .$$

Each of the n̅ amplitude symbols may correspond to (M−1) bits, which may respectively contribute 1-bit to the bit sequences, which in total give rise to n̅(M−1) amplitude bits. The n̅(M−1) amplitude bits and an yn̅ extra information bits, denoted by u^{γn̅}, may together constitute n̅(M−1+γ) bits, which may be input to a system FEC encoder with rate R_{c}=(M−1+γ)/M. The FEC encoder may generate n̅(1−γ) parity bits denoted by p^{n̅(1-γ)}. These n̅(1−γ) parity bits together with the γn extra information bits, together constituting

$${b}_{1}^{\overline{n}} ,$$

may be converted to n̅ sign bits. The n̅ sign bits may be pointwise multiplied with the n̅ amplitudes symbols in s^{n̅}. The transmission rate associated with the transmitter chain may be Rₜ=Rₐₛ+γ.

Regarding alphabets [symbol] , [symbol] ={a₁, a₂, . . . , a_{m̅}} may be a second alphabet having a second alphabet size m̅>1, where each element of [symbol] may be called a symbol. An ordering less than on the alphabet [symbol] may be imposed, such that aᵢ<aᵢ₊₁ for any i ϵ{1, 2, . . . , m̅−1} (e.g., a₁<a₂< . . . <a_{m̅}). For each integer m between 1 and m̅, [symbol] may be the subset of [symbol] consisting of symbol aᵢ for all i≤m, such that [symbol] ={aᵢ ϵ [symbol] |i≤m}. For example, [symbol] ={a₁}, [symbol] ={a₁, a₂} and [symbol] ={a₁, a₂, . . . , a_{m̅-1}}, and [symbol] ⊂ [symbol] ⊂ . . . ⊂ [symbol] . [symbol] may be referred to as a first alphabet, and may have a first alphabet size m, and may be a subset or equal to the second alphabet.

Regarding a symbol energy, given a second alphabet [symbol] {a₁, a₂, . . . , a_{m̅}} of size m̅, E(aᵢ) may denote the energy of symbol aᵢ for each i. Symbol energies may be distinct and an induced ordering may be present among energies, for example, for any i ϵ{1, 2, . . . , m̅−1}, such that 0≤E(aᵢ)<E(aᵢ₊₁).

Regarding examples of [symbol] and symbol energy, in a 2^{M}-ary ASK constellation, [symbol] ={1, 3, . . . , 2^{M}−1} so that m=2^{M-1} (e.g., m depends on the modulation order) and {−1, 1}× [symbol] corresponds to the 2^{M}-ary ASK constellation. In this case, aᵢ=2i−1 so that a₁=1, a₂=3, . . . , a_{m̅}=2^{M}−1. In a first example, for each i, the energy E(aᵢ) of symbol aᵢ may be E(aᵢ)=(2i−1)². In a second example, for each i, the energy E(aᵢ) of symbol aᵢ may be E(aᵢ)=i(i−1)/2. Since 8E(aᵢ)+1=(2i−1)², E(aᵢ) in the second example may involve a shifted scaling of (2i−1)² in the first example.

Regarding a sequence energy, for the first alphabet [symbol] of size m, a sequence s=(s₁, s₂, . . . , sₙ) of a first sequence length n and over [symbol] may be considered. The length of the sequence may be equal to n, and each element of the sequence may belong to the first alphabet [symbol] . The energy of the sequence s, denoted by E(s), may be defined as an accumulation (e.g., a summation) of all its symbol energies, in accordance with:

$$E ( s ) = {\sum }_{l = 1}^{n} E ( {s}_{l} ) .$$

Regarding a cumulative sequence quantity

$${N}_{c}^{[ m ]} ( n , E ) ,$$

[symbol]

={a₁, a₂, . . . , aₘ} may be the first alphabet of size m satisfying that, for each i ϵ{1, 2, . . . , m}, symbol aᵢ has an energy E(aᵢ). Further, [symbol] (m, n, E)≅{s|sᵢϵ [symbol] , iϵ{1, 2, . . . , n}, E(s)≤E} may denote the set of all sequences of length n and over [symbol] , such that each sequence in this set has an energy at most equal to a first sequence energy E. Further,

$${N}_{c}^{[ m ]} ( n , E )$$

may denote the cardinality of [symbol] (m, n, E) (e.g., the total number of distinct sequences in the set [symbol] (m, n, E)), such that

$${N}_{c}^{[ m ]} ( n , E ) = \vert S ( m , n , E ) \vert .$$

When the alphabet size m is clear from context, the superscript “^{[m]}” may be omitted and N_{c}(n, E) may be written as a proxy. For a given m, N_{c}(n, E) may be a two-variable integer-valued function of n and E.

Cumulative sequence quantities N_{c} may be associated with energy-based shaping. In an energy-based shaping scheme, given a symbol alphabet [symbol] , a sequence length n̅ and an energy threshold Ē, an energy-based shaping scheme may encode a plurality of k information bits to a symbol sequence in [symbol] (m̅, n̅, Ē), which may be using a direct arithmetic coding (AC) technique or a peeling technique. Encoding techniques may induce an injective mapping from the set of all 2^{k} bit sequences to [symbol] (m̅, n̅, Ē). Encoding techniques may be employed by a distribution matcher in a PAS architecture.

Regarding a computation complexity and a storage complexity, typically, m̅ may be relatively small while sequence length n and energy threshold Ē may be relatively large. Encoding techniques generally require knowledge of

$${N}_{c}^{[ m ]} ( n , E )$$

for a dynamic range of values of n and E and one or more values of m, where 1<m≤m̅, 0≤n≤n̅, and 0≤E≤Ē. A straightforward computation for a value of

$${N}_{c}^{[ m ]} ( n , E )$$

may have a computation complexity quadratic in n. Moreover, such a value may have a relatively large magnitude, so that a straightforward tabulation technique to accurately store all such values for a wide range of values of n and E may have a storage complexity that is prohibitively large.

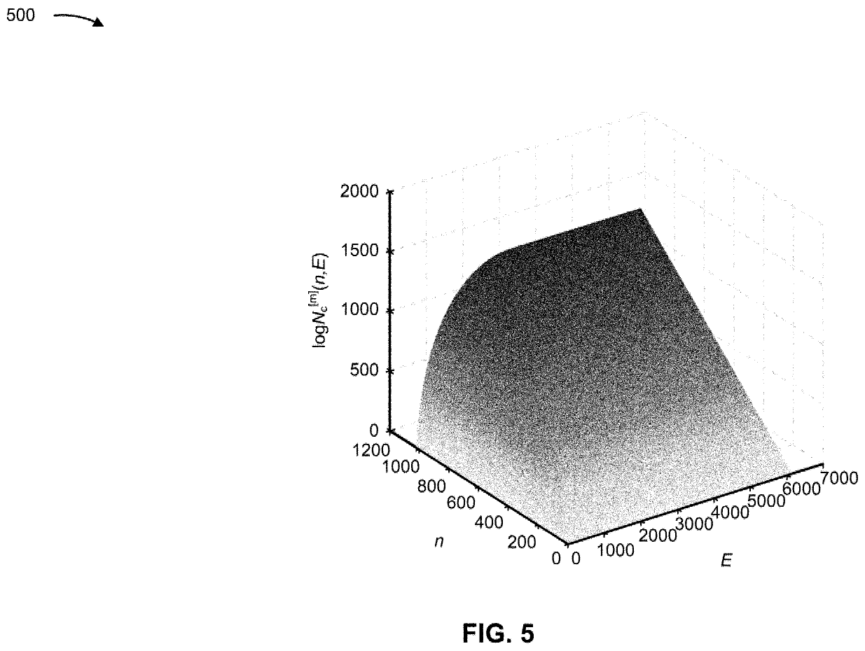

FIG. 5 is a diagram illustrating an example 500 of logarithm(s) of cumulative sequence quantities, in accordance with the present disclosure.

As shown in FIG. 5, log N_{c}(n, E) for an alphabet [symbol] ={a₁, a₂, a₃, a₄} may be defined, where n ranges from 1 to 1000, and for each n, E ranges from 0 to 6n. Symbol energies may be E(a₁)=0, E(a₂)=1, E(a₃)=3 and E(a₄)=6. In other words, log

$${N}_{c}^{[ m ]} ( n , E )$$

is shown as a two-variable function of n and E, for an m.

As indicated above, FIG. 5 is provided as an example. Other examples may differ from what is described with regard to FIG. 5.

An approximation for N_{c} may be performed, such that an ultra-high approximation accuracy may be guaranteed, but a further reduction in complexity may be needed. An approximation of log N_{c}(n, E) may be denoted by log \hat{N}_{c}(n, E) and may be determined in accordance with:

$$log {\hat{N}}_{c} ( n , E ) = n {H}^{s a t} ( ω ) + {G}_{0}^{c} ( ω ) + {G}_{0}^{s} ( v ) + \frac{1}{\sqrt{n}} {G}_{\frac{1}{2}}^{s} ( v ) + \frac{1}{n} {G}_{1}^{c} ( ω ) + \frac{1}{n} {G}_{1}^{s} ( v ) + c ( E ) .$$

Another approximation of log N_{c}(n, E) may be determined in accordance with:

$$log {\hat{N}}_{c} ( n , E ) = n {H}^{s a t} ( ω ) + {G}_{l g} ( ω ) log n + {G}_{0}^{c} ( ω ) + \frac{1}{n} {G}_{1}^{c} ( ω ) + c ( E ) ,$$

where H^{sat} is a saturated entropy function associated with an underlying alphabet [symbol] .

Further, a normalized energy may be represented by

$$ω = \frac{E}{n} ,$$

a centralized and scaled energy may be represented by v=\sqrt{n}(ω−ω^{u}), and a uniform energy over [symbol] may be represented by:

$${ω}^{u} = \frac{1}{m} {\sum }_{i = 1}^{m} E ( {a}_{i} ) .$$

Except for c(E), each of the remaining functions may depend on the underlying alphabet [symbol] .

When the normalized energy ω is smaller than the uniform energy ω^{u} over [symbol] , the value of the saturated entropy function H^{sat} evaluated at the normalized energy ω is equal to a value of the Shannon entropy associated to a Maxwell-Boltzmann (MB) distribution over [symbol] and with a parameter β, where the parameter β is equal to a first-order derivative of the saturated entropy function H^{sat} evaluated at the normalized energy ω. When the value of the normalized energy ω is larger than or equal to the uniform energy ω^{u} over [symbol] , then the saturated entropy function H^{sat} evaluated at the normalized energy ω is equal to a logarithm of a size of [symbol] ; that is, log m.

Regarding considerations on complexity, evaluating each above term for any pair of n and E may be of medium complexity. The evaluation of each above term may involve solving for the root λ=λ(ω) of a polynomial equation Z₁(λ)/Z₀(λ)=ω may be in accordance with:

$${Z}_{1} ( x ) = {\sum }_{i = 1}^{m} E ( {a}_{i} ) {x}^{E ( {a}_{i} )} and$$

$${Z}_{0} ( x ) = {\sum }_{i = 1}^{m} {x}^{E ( {a}_{i} )} .$$

The evaluation of each above term may involve taking the logarithm of a real positive number in, for example, a

$${G}_{0}^{c} ( ω )$$

term. The evaluation of each above term may involve taking powers of real numbers while the powers increase with m. Functions like the saturated entropy function H^{sat} may be smooth functions over [0, E(aₘ)]. Thus, approximating log N_{c}(n, E) may involve approximating these functions using simpler alternatives.

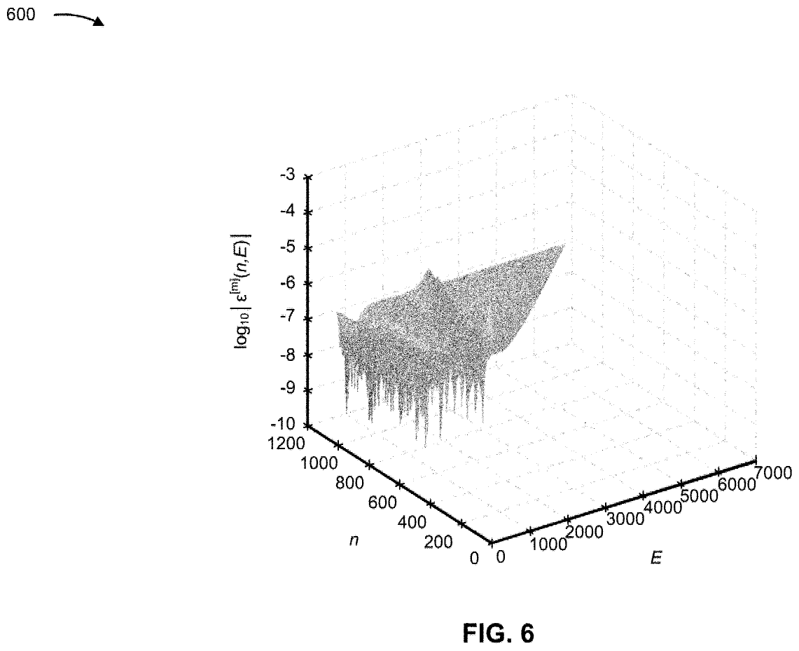

FIG. 6 is a diagram illustrating an example 600 of absolute errors of approximation, in accordance with the present disclosure.

As shown in FIG. 6, an approximation associated with log₁₀|log N_{c}−log \hat{N}_{c}| may be calculated, where log N_{c} is associated with a true value and \hat{N}_{c} is associated with an approximate value. The approximation may be associated with absolute errors of approximation under a log-10 scale. The approximation may be in terms of n and E. The calculation may be associated with an ultra-high approximation accuracy, but may involve a relatively high complexity.

As indicated above, FIG. 6 is provided as an example. Other examples may differ from what is described with regard to FIG. 6.

In various aspects of techniques and apparatuses described herein, a transmitter device (e.g., a UE or a network node) may obtain a plurality of information bits (k information bits) for a probabilistic shaping scheme. The probabilistic shaping scheme may be associated with an energy threshold (Ē). The energy threshold (Ē) may be associated with a maximum sequence energy. The transmitter device may form, as part of the probabilistic shaping scheme, polynomial approximations of a plurality of approximation factors. The transmitter device may obtain, using the polynomial approximations of the plurality of approximation factors, an approximation of a logarithm of a cumulative sequence quantity (N_{c}(n, E)). The logarithm of the cumulative sequence quantity may be associated with a first alphabet ( [symbol] ) having a first alphabet size (m), a first sequence length (n), and a first sequence energy (E). The transmitter device may perform an exponentiation operation on the approximation of the logarithm of the cumulative sequence quantity, thereby obtaining an approximation of the cumulative sequence quantity. The transmitter device may encode, as part of the probabilistic shaping scheme, the plurality of information bits to obtain a symbol sequence (s^{n̅}) based at least in part on the approximation of the cumulative sequence quantity. The symbol sequence may have a length equal to a second sequence length (n̅) and an energy (E(s^{n̅})) less than or equal to the energy threshold. Each symbol of the symbol sequence may belong to a second alphabet ( [symbol] ) having a second alphabet size (m̅). The transmitter device may transmit a message to one or more receiver devices based at least in part on the symbol sequence. In some aspects, by using the polynomial approximations, a very high approximation accuracy may be guaranteed with a reduced complexity, which may improve a performance of the transmitter device. For example, implementing the polynomial approximations may reduce a power consumption of the transmitter device.

FIG. 7 is a diagram illustrating an example 700 associated with polynomial approximation techniques for probabilistic amplitude shaping, in accordance with the present disclosure. As shown in FIG. 7, example 700 includes communication between a transmitter device (e.g., UE 120 or network node 110) and a receiver (e.g., network node 110 or UE 120). In some aspects, the transmitter device and the receiver may be included in a wireless network, such as wireless network 100.

As shown by reference number 702, the transmitter device may obtain a plurality of information bits (k information bits) for a probabilistic shaping scheme. The probabilistic shaping scheme may be associated with an energy threshold (Ē). The probabilistic shaping scheme may be an energy-based probabilistic amplitude shaping scheme involving a polynomial approximation.

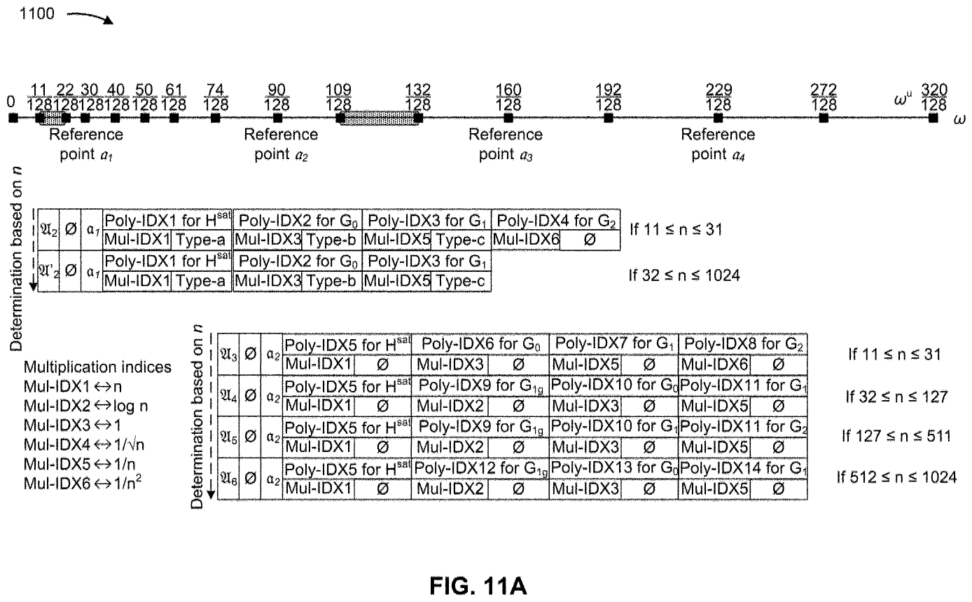

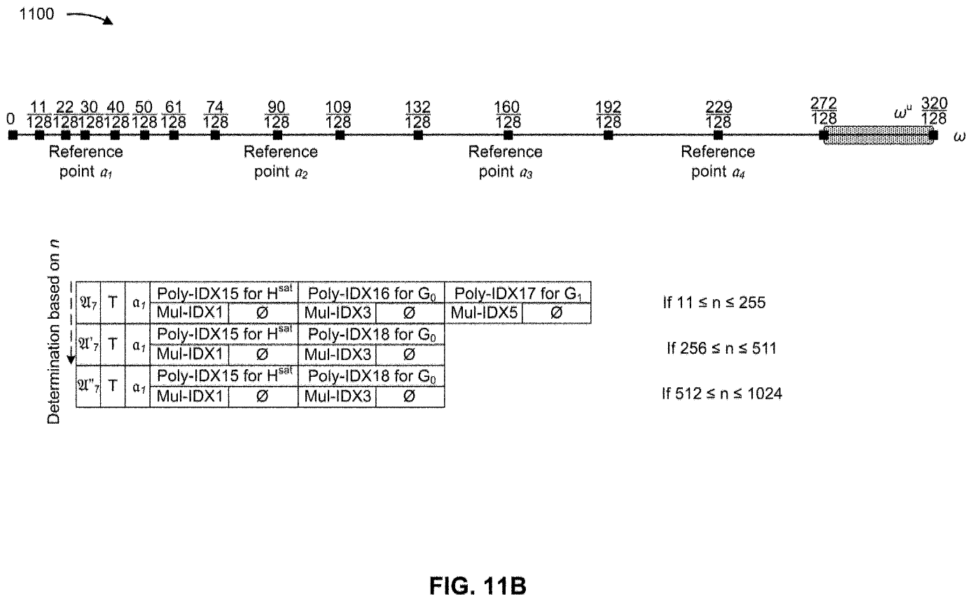

As shown by reference number 704, the transmitter device may form, as part of the probabilistic shaping scheme, polynomial approximations of a plurality of approximation factors. In some aspects, when forming the polynomial approximations of the plurality of approximation factors, the transmitter device may determine a normalized energy (ω) corresponding to a ratio between a first sequence energy (E) and the first sequence length (n). The transmitter device may obtain a uniform energy (ω^{u}), where the uniform energy may be associated with the first alphabet ( [symbol] ). The transmitter device may obtain a subinterval of an interval based at least in part on the normalized energy (examples of intervals are shown in FIGS. 11A, 11B, 12 and 13). The transmitter device may utilize the subinterval of the interval and the normalized energy to form at least one of the polynomial approximations of the plurality of approximation factors.

In some aspects, the interval may be associated with the first alphabet. The interval may include a plurality of subintervals, and the interval may correspond to a disjoint union of the plurality of subintervals. Each subinterval, of the plurality of subintervals of the interval, may correspond to a respective left subinterval boundary of a plurality of left subinterval boundaries.

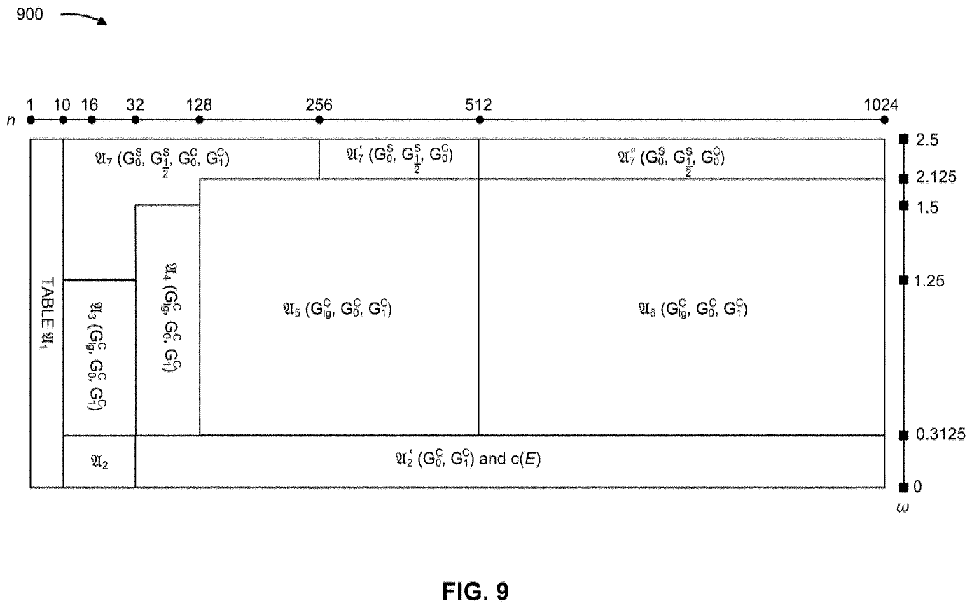

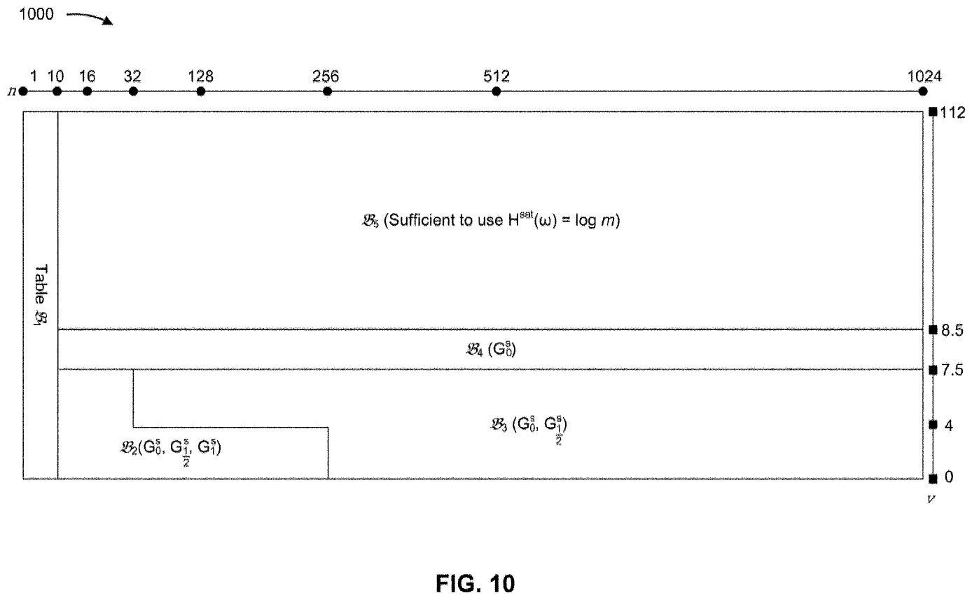

In some aspects, each subinterval, of the plurality of subintervals of the interval, may be associated with one or more respective approximation region indices (examples of approximation regions are shown in FIGS. 9 and 10). Each one of the one or more respective approximation region indices may be associated with a respective reference point of a plurality of reference points, a respective additional indices, and/or one or more respective polynomial coefficient indices, where each polynomial coefficient index, of the one or more respective polynomial coefficient indices, may be associated with a respective multiplication index of a plurality of multiplication indices and a respective type indicator of a plurality of type indicators.

In some aspects, one or more reference points of the plurality of reference points may correspond to dyadic numbers. One or more left subinterval boundaries of the plurality of subintervals of the interval may correspond to dyadic numbers. One or more reference points of the plurality of reference points may coincide with one or more respective left subinterval boundaries of the plurality of left subinterval boundaries. A total number of reference points of the plurality of reference points may be smaller than a total number of left subinterval boundaries of the plurality of subintervals of the interval. In some aspects, the plurality of left subinterval boundaries may be stored as a binary tree structure having a root node, a plurality of internal nodes, and a plurality of leaf nodes. Each internal node, of the plurality of internal nodes, may store one key that corresponds to a respective left subinterval boundary. Each leaf node, of the plurality of leaf nodes, may store one subinterval index that corresponds to a respective subinterval of the plurality of subintervals of the interval.

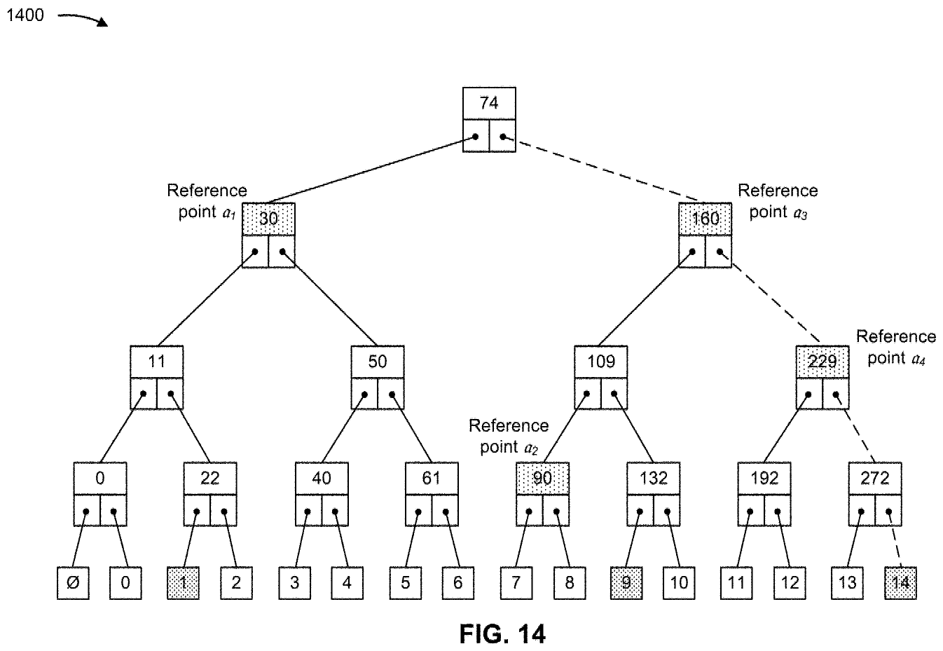

In some aspects, the transmitter device, when obtaining the subinterval of the interval, may perform a binary search by traversing a path of the binary tree structure from the root node to a leaf node of the plurality of leaf nodes (an example of a subinterval search is shown in FIG. 14). The leaf node, of the plurality of leaf nodes, may store a subinterval index that corresponds to the subinterval of the interval. The transmitter device may identify the subinterval of the interval based at least in part on the subinterval index. The transmitter device may determine an approximation region index based at least in part on the first sequence length and the identifying of the subinterval of the interval. The transmitter device may identify one or more polynomial coefficient indices, where the one or more polynomial coefficient indices may be associated with the approximation region index. The transmitter device may identify a respective multiplication index for each polynomial coefficient index of the one or more polynomial coefficient indices. The transmitter device may identify a respective type indicator for each polynomial coefficient index of the one or more polynomial coefficient indices.

In some aspects, when performing the binary search, the transmitter device may determine a difference between the normalized energy and a reference point corresponding to the subinterval of the interval. The difference may refer to a subtraction between the normalized energy and the reference point. In other words, the difference refers to the normalized energy minus the reference point. In some aspects, when performing the binary search, the transmitter device may determine a difference between a centralized and scaled energy (v) and a reference point corresponding to the subinterval of the interval, where the centralized and scaled energy may correspond to a square root of the first sequence length multiplying a difference between the normalized energy and the uniform energy.

In some aspects, when utilizing the subinterval of the interval and the normalized energy, the transmitter device may compute one or more polynomial values, where each polynomial value, of the one or more polynomial values, may correspond to a respective polynomial coefficient index of the one or more polynomial coefficient indices. The transmitter device may determine one or more multiplication factors, where each multiplication factor, of the one or more multiplication factors, may be based at least in part on a multiplication index being associated to a respective polynomial coefficient index of the one or more polynomial coefficient indices. The transmitter device may determine one or more approximation terms, where each approximation term, of the one or more approximation terms, may be based at least in part on a multiplication of a respective polynomial value, of the one or more polynomial values, and a respective multiplication factor, of the one or more multiplication factors.

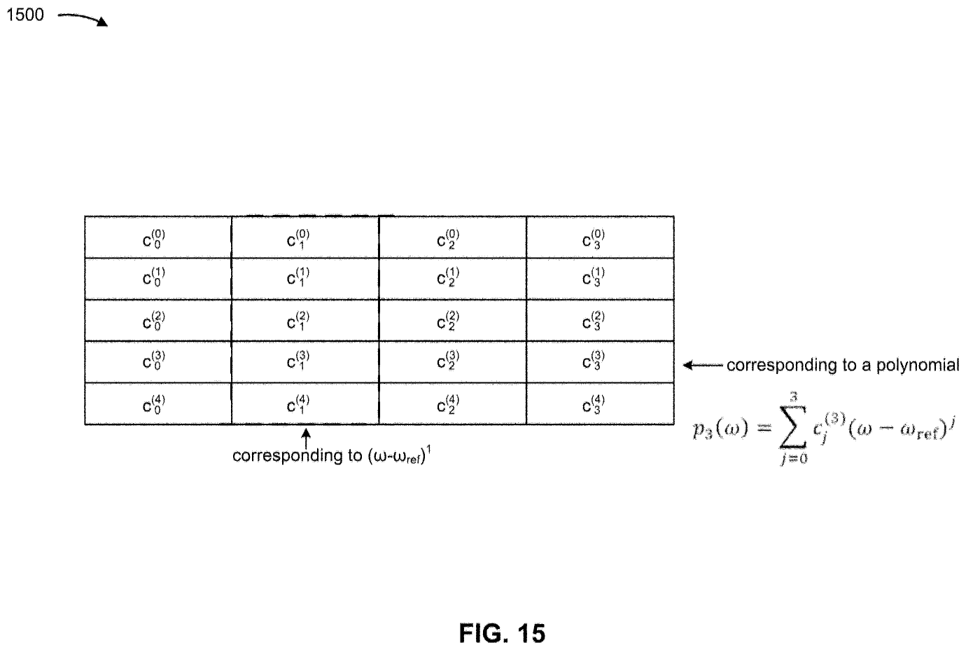

In some aspects, each respective polynomial approximation may be based at least in part on a plurality of polynomial coefficients and a polynomial degree. The plurality of polynomial coefficients and the polynomial degree may be stored in a memory of the transmitter device (an example of a storage of polynomial coefficients is shown in FIG. 15). The plurality of polynomial coefficients may be stored in a lookup table.

In some aspects, when forming the polynomial approximations of the plurality of approximation factors, the transmitter device may determine an approximation region based at least in part on the first sequence length and the first sequence energy. The approximation region may be associated with the first alphabet. The transmitter device may identify an approximation form that corresponds to the approximation region. The transmitter device may form the polynomial approximations of the plurality of approximation factors based at least in part on the identifying of the approximation form. In some aspects, when forming the polynomial approximations of the plurality of approximation factors, the transmitter device may remove singularities from at least one of the polynomial approximations of the plurality of approximation factors.

As shown by reference number 706, the transmitter device may obtain, using the polynomial approximations of the plurality of approximation factors, an approximation of a logarithm of a cumulative sequence quantity (N_{c}(n, E)). The logarithm of the cumulative sequence quantity may be associated with the first alphabet having the first alphabet size, the first sequence length, and the first sequence energy. The cumulative sequence quantity may define a cardinality of a set of all sequences over the first alphabet. Each sequence, of the set of all sequences over the first alphabet, may have a respective length equal to the first sequence length and a respective energy less than or equal to the first sequence energy.

In some aspects, when obtaining the approximation of the logarithm of the cumulative sequence quantity, the transmitter device may multiply each polynomial approximation, of the polynomial approximations of the plurality of approximation factors, by a respective multiplicative factor. The respective multiplicative factor may be based at least in part on the first sequence length. The transmitter device may obtain a plurality of approximation terms based at least in part on the multiplying of each polynomial approximation. Each approximation term, of the plurality of approximation terms, may correspond to a respective polynomial approximation of the polynomial approximations of the plurality of approximation factors. The transmitter device may sum the plurality of approximation terms to obtain the approximation of the logarithm of the cumulative sequence quantity.

In some aspects, the polynomial approximations of the plurality of approximation factors may include a first piecewise polynomial approximation of a saturated entropy function (H^{sat}) of the normalized energy. The saturated entropy function may correspond to a first approximation factor of the plurality of approximation factors. The saturated entropy function may be associated with the first alphabet. The polynomial approximations of the plurality of approximation factors may include a respective piecewise polynomial approximation corresponding to each of one or more additional functions. Each of the one or more additional functions may be a function of the normalized energy or the centralized and scaled energy.

As shown by reference number 708, the transmitter device may perform an exponentiation operation on the approximation of the logarithm of the cumulative sequence quantity, thereby obtaining an approximation of the cumulative sequence quantity. The logarithm, of the cumulative sequence quantity, is under a base of 2, and the transmitter device may perform the exponentiation operation under a base of 2.

As shown by reference number 710, the transmitter device may encode, as part of the probabilistic shaping scheme, the plurality of information bits to obtain a symbol sequence (s^{n̅}) based at least in part on the approximation of the cumulative sequence quantity. The symbol sequence may have a length equal to a second sequence length (n̅) and an energy less than or equal to the energy threshold. Each symbol of the symbol sequence may belong to a second alphabet ( [symbol] ) having a second alphabet size (m̅). The probabilistic shaping scheme may be associated with the second alphabet and the second sequence length. The second alphabet size may be greater than 1. The second alphabet may include a plurality of amplitude symbols. The first alphabet may be a subset of or equal to the second alphabet. The first sequence length may be less than or equal to the second sequence length. The first sequence energy may be less than or equal to the energy threshold. The second sequence length may be a power of 2. The first sequence length may be a power of 2. In other words, the second sequence length and the first sequence length may be equal to numbers that are powers of 2 (e.g., the number 16, which is 24) or may be equal to 2 to the power of an integer.

As shown by reference number 712, the transmitter device may transmit a message to one or more receiver devices based at least in part on the symbol sequence. For example, a UE may transmit the message to another UE or a network node based at least in part on the symbol sequence. A network node may transmit the message to another network node or a UE based at least in part on the symbol sequence.

As indicated above, FIG. 7 is provided as an example. Other examples may differ from what is described with regard to FIG. 7.

In some aspects, the transmitter device (e.g., a UE or a network node) may obtain the plurality of k information bits. The transmitter device may encode the plurality of k information bits to the symbol sequence s^{n̅} based at least in part on an energy-based probabilistic shaping scheme involving the polynomial approximation. The polynomial approximation may involve a piecewise polynomial approximation of the cumulative sequence quantity N_{c}(n, E) for one or more values of the first alphabet size m, the first sequence length n, and/or the first sequence energy E associated with the first alphabet [symbol] . The encoding of the plurality of k information bits to the symbol sequence s^{n̅} may be based it least in part on the cumulative sequence quantity N_{c}(n, E). The encoding of the plurality of k information bits to the symbol sequence s^{n̅} may be for the second alphabet [symbol] , the second sequence length n, and the energy threshold Ē. Polynomial approximation may be used to approximate N_{c}(n, E) for one or more values of m, n and E, and such values may be used for encoding. The first alphabet [symbol] may be a subset of or equal to the second alphabet [symbol] . The first sequence length n may be less than or equal to the second sequence length n̅. The first sequence energy E may be less than or equal to the energy threshold Ē.

In some aspects, the transmitter device may perform the polynomial approximation to obtain the cumulative sequence quantity N_{c}(n, E). When performing the polynomial approximation, the transmitter device may perform an interval search based at least in part on an interval to obtain a subinterval. Given the first alphabet [symbol] , the first sequence length n and the first sequence energy E, the transmitter device may perform the interval search based at least in part on the interval to obtain the subinterval. The interval search may be based at least in part on a binary search tree structure. The binary search tree structure may be based at least in part on the normalized energy ω or the centralized and scaled energy v. One or more reference points may be obtained based at least in part on the interval for usage in polynomial evaluations associated with the polynomial approximation. The transmitter device may determine an approximation form based at least in part on the first sequence length n and the subinterval. Polynomial coefficient indices associated with the subinterval may correspond to polynomial coefficients that are stored in a lookup table.

In some aspects, the transmitter device may compute a value of each polynomial of the normalized energy a or the centralized and scaled energy v to obtain polynomial values. The transmitter device may compute a value of each approximation term of the one or more approximation terms, of the approximation form, based at least in part on the first sequence length n and the polynomial values. The transmitter device may approximate the logarithm of the cumulative sequence quantity N_{c}(n, E) based at least in part on a sum of approximation terms. The transmitter device may exponentiate an approximation of the logarithm of the cumulative sequence quantity N_{c}(n, E) to obtain an approximation of the cumulative sequence quantity N_{c}(n, E).

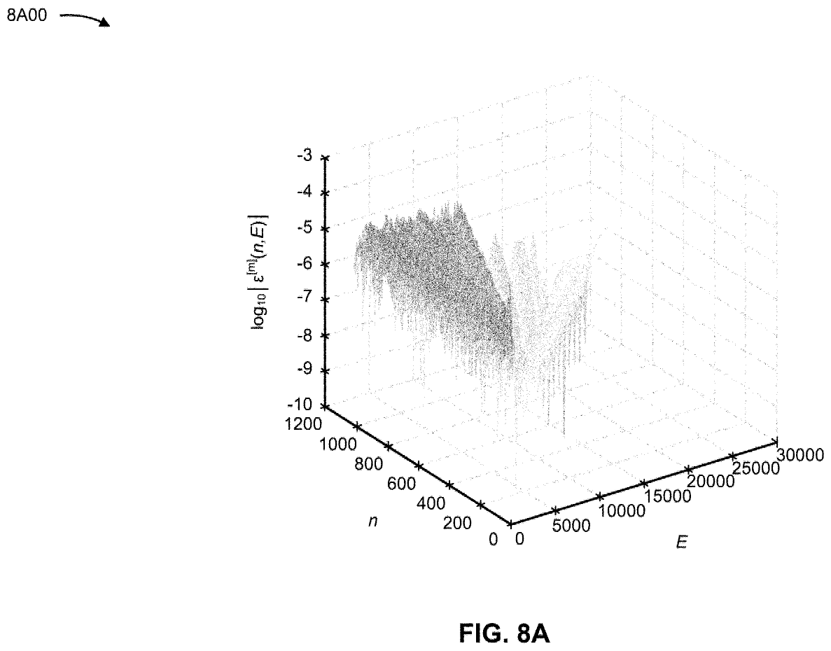

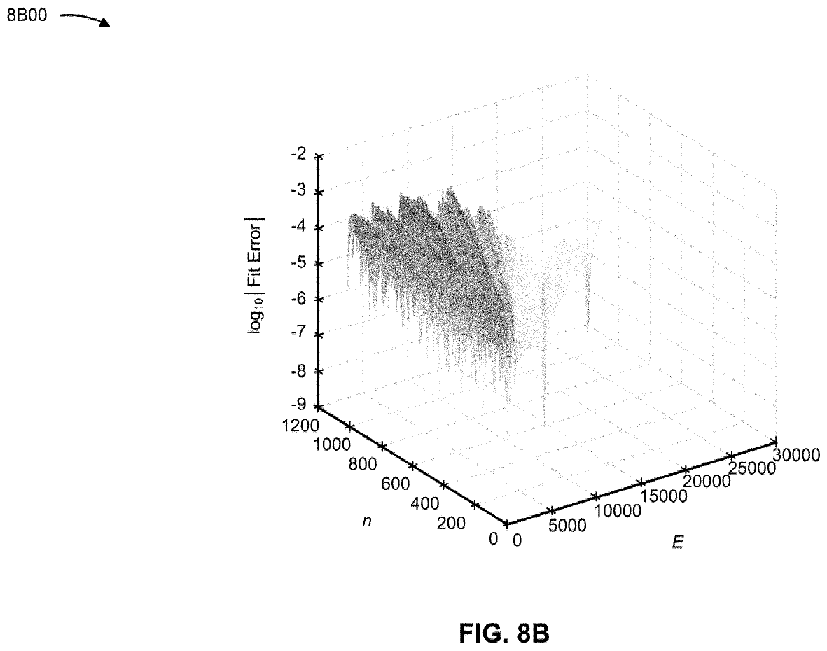

FIGS. 8A and 8B are diagrams illustrating an example 800 associated with absolute errors of approximation, in accordance with the present disclosure.

In some aspects, a numerical evaluation with m=8 and QAM-256 may be based at least in part on a piecewise polynomial approximation technique. As in FIG. 8A, a high-accuracy scenario for m=8 may have a worst-case absolute error 0.0007 for all n≥32. The total number of polynomial pieces may be 152. All polynomials may be of degree 3. The fixed storage of polynomial coefficients may be 1824 bytes, with 3 bytes per coefficient. As shown in FIG. 8B, a low-accuracy example for m=8 may have a worst-case absolute error 0.0014 for all n≥32. The total number of polynomial pieces may be 67. All polynomials may be of degree 3. The fixed storage of polynomial coefficients may be 804 bytes, with 3 bytes per coefficient.

As indicated above, FIGS. 8A and 8B are provided as an example. Other examples may differ from what is described with regard to FIGS. 8A and 8B.

In some aspects, the first alphabet [symbol] may be associated with a first feasible region [symbol] and a second feasible region [symbol] . Each of the first feasible region [symbol] and the second feasible region [symbol] may be a disjoint union of one or more subsets. Each subset of the one or more subsets may correspond to an approximation region. The approximation region may be associated with the approximation form. The approximation form may be the sum of one or more approximation terms. Each of the one or more approximation terms may include an approximation factor that corresponds to a polynomial of the normalized energy a or the centralized and scaled energy v. Each of the one or more approximation terms may include a multiplicative factor that depends on the first sequence length n. One approximation term may be a function of the first sequence energy E.

In some aspects, approximation regions may be tailored for relatively fast and accurate approximation. Regarding feasible regions and approximating regions, for the alphabet [symbol] ={a₁, a₂, . . . , aₘ}, E(aᵢ) may be the energy of symbol aᵢ such that E(aₘ) is the maximum symbol energy. For integers nₘᵢₙ and nₘₐₓ such that 1≤nₘᵢₙ<nₘₐₓ, feasible regions [symbol] and [symbol] associated with [symbol] may be defined as:

$${ℒ}_{m} = \{ ( n , ω ) \vert {n}_{min} \leq n \leq {n}_{max} , 0 \leq ω \leq {ω}^{u} \} ,$$

$${ℛ}_{m} = \{ ( n , v ) \vert {n}_{min} \leq n \leq {n}_{max} , 0 \leq v \leq {v}_{max} \} .$$

Here, nₘᵢₙ and nₘₐₓ are nₘᵢₙ=1 and nₘₐₓ=1024, and ω^{u} may be the uniform energy associated to [symbol] . Each feasible region [symbol] or [symbol] may be the disjoint union of the one or more subsets. Each subset may be referred to as the approximation region, and the total number of approximation regions may be denoted by Jₘ and Kₘ. As a result:

$${ℒ}_{m} = {⋃}_{i = 1}^{{J}_{m}} {𝔘}_{i}^{[ m ]}$$

$${ℛ}_{m} = {⋃}_{i = 1}^{{K}_{m}} {𝔅}_{i}^{[ m ]} .$$

For example, i indexes the approximating regions, and [symbol] may be the approximating region (e.g., [symbol] may be written as a proxy for [symbol] when [symbol] is clear).

In some aspects, each approximation region may be associated with the approximation form. Each approximation form may be written as the sum of the one or more approximation terms. Each approximation term may consist of the approximation factor that corresponds to the polynomial of the normalized energy ω or the centralized and scaled energy v. Each approximation term may consist of the multiplicative factor that depends only on n (e.g., factors like n, log n, or 1). The approximation term may be a function of E, whose values may be tabulated.

FIG. 9 is a diagram illustrating an example 900 associated with approximation regions, in accordance with the present disclosure.

In some aspects, the normalized energy ω may be between zero and a uniform energy ω^{u} associated with the first alphabet [symbol] . The first feasible region [symbol] may include a plurality of approximation regions. The approximation region of the plurality of approximation regions may be based at least in part on a storage of the cumulative sequence quantity N_{c}(n, E) using a lookup table, the first sequence length n, a saturated entropy function H^{sat}, the normalized energy ω, the first sequence energy E, and/or the centralized and scaled energy v.

As shown in FIG. 9, approximation regions in [symbol] may be calculated for the m=4, 1≤n≤1024 and 0≤ω<ω^{u} case. For example, 1, 10, 16, 32, 128, 256, 512, or 1024, and 0, 0.3125, 1.25, 1.5, 2.215, or 2.5 may be used to differentiate the boundaries of the approximation regions in [symbol] . The approximation regions in [symbol] may include [symbol] (table),

$${𝔘}_{2} , {𝔘}_{2}^{′} ( {G}_{0}^{c} , {G}_{1}^{c} ) and c ( E ) , {𝔘}_{3} ( {G}_{0}^{c} , {G}_{1}^{c} , {G}_{2}^{c} ) , {𝔘}_{4} ( {G}_{lg}^{c} , {G}_{0}^{c} , {G}_{1}^{c} ) ,$$

$${𝔘}_{5} ( {G}_{lg}^{c} , {G}_{0}^{c} , {G}_{1}^{c} ) , {𝔘}_{6} ( {G}_{lg}^{c} , {G}_{0}^{c} , {G}_{1}^{c} ) , {𝔘}_{7} ( {G}_{0}^{s} , {G}_{\frac{1}{2}}^{s} , {G}_{1}^{s} , {G}_{0}^{c} , {G}_{1}^{c} ) ,$$

$${𝔘}_{7}^{′} ( {G}_{0}^{s} , {G}_{\frac{1}{2}}^{s} , {G}_{0}^{c} ) , and {𝔘}_{7}^{″} ( {G}_{0}^{s} , {G}_{\frac{1}{2}}^{s} , {G}_{0}^{c} ) .$$

Regarding approximation forms for [symbol] , the approximation region [symbol] may correspond to the storage of N_{c}(n, E) or log N_{c}(n, E) using look-up tables (e.g., fixed read-only memory (ROM) storage). For example, the approximation region [symbol] corresponds to cases when ω is between 0 and ω^{u} and n is below or equal to 10. In other words, when n and ω are in these specified ranges, log \hat{N}_{c}(n, E) may be approximated using tabulated values, where E=ωn. For approximation regions [symbol] or

$${𝔘}_{2}^{′} ,$$

the associated approximation forms may be respectively given by:

$$log {\hat{N}}_{c} ( n , E ) = {nH}^{s a t} ( ω ) - \frac{1}{2} log n + {G}_{0}^{c} ( ω ) + \frac{1}{n} {G}_{1}^{c} ( ω ) + \frac{1}{{n}^{2}} {G}_{2}^{c} ( ω ) + c ( E ) ,$$

$$log {\hat{N}}_{c} ( n , E ) = n {H}^{s a t} ( ω ) - \frac{1}{2} log n + {G}_{0}^{c} ( ω ) + \frac{1}{n} {G}_{1}^{c} ( ω ) + c ( E ) ,$$

where the log could be under base 2, though other choices may be possible (e.g., natural log). For example, the approximation region [symbol] corresponds to cases when ω is between 0 and 0.3125 and n is between 32 and 1024. The symbols in the brackets (e.g., for [symbol] , H^{sat},

$${G}_{0}^{c} , {G}_{1}^{c} and {G}_{2}^{c} )$$

may be used to partially indicate the approximation factors that are associated with the corresponding approximation region. For approximation region [symbol] , the associated approximation form may be respectively given by:

$$log {\hat{N}}_{c} ( n , E ) = n {H}^{s a t} ( ω ) - \frac{1}{2} log n + {G}_{0}^{c} ( ω ) + \frac{1}{n} {G}_{1}^{c} ( ω ) + \frac{1}{{n}^{2}} {G}_{2}^{c} ( ω ) .$$

For example, the approximation region [symbol] corresponds to cases when ω is between 0.3125 and 1.25 and n is between 10 and 32. For approximation regions [symbol] , [symbol] or [symbol] , the associated approximation form may be given by:

$$log {\hat{N}}_{c} ( n , E ) = n {H}^{s a t} ( ω ) + {G}_{lg}^{c} ( ω ) log n + {G}_{0}^{c} ( ω ) + \frac{1}{n} {G}_{1}^{c} ( ω ) .$$

For example, the approximation region [symbol] corresponds to cases when ω is between 0.3125 and 1.5 and n is between 32 and 128, the approximation region [symbol] corresponds to cases when ω is between 0.3125 and 2.125 and n is between 128 and 512, and the approximation region [symbol] corresponds to cases when ω is between 0.3125 and 2.125 and n is between 512 and 1024. For approximation region [symbol] , the associated approximation form may be given by:

$$log {\hat{N}}_{c} ( n , E ) = n {H}^{s a t} ( ω ) + {G}_{0}^{c} ( ω ) + {G}_{0}^{s} ( v ) + \frac{1}{\sqrt{n}} {G}_{\frac{1}{2}}^{s} ( v ) + \frac{1}{n} {G}_{1}^{c} ( ω ) + \frac{1}{n} {G}_{1}^{s} ( v ) .$$

For approximation regions [symbol] or [symbol] the associated approximation form may be given by:

$$log {\hat{N}}_{c} ( n , E ) = n {H}^{s a t} ( ω ) + {G}_{0}^{c} ( ω ) + {G}_{0}^{s} ( v ) + \frac{1}{\sqrt{n}} {G}_{\frac{1}{2}}^{s} ( v ) .$$

For example, the approximation region [symbol] corresponds to cases when ω is between 2.125 and 2.5 and n is between 256 and 512, and the approximation region [symbol] corresponds to cases when ω is between 2.125 and 2.5 and n is between 512 and 1024.

As indicated above, FIG. 9 is provided as an example. Other examples may differ from what is described with regard to FIG. 9.

FIG. 10 is a diagram illustrating an example 1000 associated with approximation regions, in accordance with the present disclosure.

In some aspects, the normalized energy ω may be between a uniform energy ω^{u} associated with the first alphabet [symbol] and a maximum symbol energy E(aₘ). The second feasible region [symbol] may include a plurality of approximation regions. The approximation region of the plurality of approximation regions may be based at least in part on a storage of the cumulative sequence quantity N_{c}(n, E) using a lookup table, the first sequence length n, the first alphabet size m, and/or the centralized and scaled energy v.

As shown in FIG. 10, approximation regions in [symbol] may be calculated for the m=4, 1≤n≤1024 and ω^{u}≤ω<E(aₘ) case. For example, 1, 10, 16, 32, 128, 256, 512, or 1024, and 0, 4, 7.5, 8.5, or 112 may be used to differentiate the boundaries of the approximation regions in [symbol] . The approximation regions in [symbol] may include [symbol] (table),

$${𝔅}_{2} ( {G}_{0}^{s} , {G}_{\frac{1}{2}}^{s} , {G}_{1}^{s} ) , {𝔅}_{3} ( {G}_{0}^{s} , {G}_{\frac{1}{2}}^{s} ) , {𝔅}_{4} ( {G}_{0}^{s} ) , and {𝔅}_{5}$$

(e.g., in this region it is sufficient to use H^{sat}(ω)=log m).

Regarding approximation forms for [symbol] , the approximation region [symbol] may correspond to the storage of N_{c}(n, E) or log N_{c}(n, E) using look-up tables (e.g., fixed ROM storage). For example, the approximation region [symbol] corresponds to cases when n is below or equal to 10. For approximation region [symbol] , the associated approximation form may be given by:

$$log {\hat{N}}_{c} ( n , E ) = n log m + {G}_{0}^{s} ( v ) + \frac{1}{\sqrt{n}} {G}_{\frac{1}{2}}^{s} ( v ) + \frac{1}{n} {G}_{1}^{s} ( v ) ,$$

where

$$\frac{1}{\sqrt{n}}$$

is a multiplicative factor,

$${G}_{\frac{1}{2}}^{s} ( v )$$

is an approximation factor, and

$$\frac{1}{\sqrt{n}} {G}_{\frac{1}{2}}^{s} ( v )$$

is an approximation term. For example, the approximation region [symbol] corresponds to cases when v is between 0 and 4 when n is between 10 and 256, and when v is between 4 and 7.5 when n is between 10 and 32. The symbols in the brackets (e.g., for [symbol] ,

$${G}_{0}^{s} , {G}_{\frac{1}{2}}^{s} , and {G}_{1}^{s} )$$

may be used to partially indicate the approximation factors that are associated with the corresponding approximation region. For approximation region [symbol] , the associated approximation form may be given by:

$$log {\hat{N}}_{c} ( n , E ) = n log m + {G}_{0}^{s} ( v ) + \frac{1}{\sqrt{n}} {G}_{\frac{1}{2}}^{s} ( v ) .$$

For example, the approximation region [symbol] corresponds to cases when v is between 0 and 4 when n is between 256 and 1024, and when v is between 4 and 7.5 when n is between 32 and 1024. For approximation region [symbol] , the associated approximation form may be given by:

$$log {\hat{N}}_{c} ( n , E ) = n log m + {G}_{0}^{s} ( v ) .$$

For example, the approximation region [symbol] corresponds to cases when v is between 7.5 and 8.5 and n is between 10 and 1024. For approximation region [symbol] the associated approximation form may be given by:

$$log {\hat{N}}_{c} ( n , E ) = n log m .$$

For example, the approximation region [symbol] corresponds to cases when v is between 8.5 and 112 and n is between 10 and 1024.

As indicated above, FIG. 10 is provided as an example. Other examples may differ from what is described with regard to FIG. 10.

In some aspects, a piecewise polynomial approximation may be associated with polynomial coefficients and degrees. A device (e.g., a transmitter device) may not need to be aware of the exact functions (e.g., the saturated entropy function H^{sat}) Rather, the device may only need to have a procedure to locate the correct polynomials and then assemble the polynomials. Thus, a polynomial approximation of an approximation factor may not imply that the device is actually aware of the approximation factor (e.g., a function).

An approximation factor corresponding to the saturated entropy function H^{sat} associate to [symbol] may be represented by H^{sat}(ω) which may be associated with a piecewise polynomial Ĥ^{sat}(ω) An approximation factor that is multiplied by log n, e.g., function

$${G}_{lg}^{c} ,$$

associated to [symbol] may be represented by

$${G}_{lg}^{c} ( ω ) ,$$

which may be associated with a piecewise polynomial

$${\hat{G}}_{lg}^{c} ( ω ) .$$

Approximation factors that are multiplied by inverse powers of n, e.g., functions

$${G}_{i}^{c}$$

for i ϵ{0, 1, 2}, associated to [symbol] may be represented by

$${G}_{i}^{c} ( ω ) ,$$

which may be respectively associated with piecewise polynomials

$${\hat{G}}_{i}^{c} ( ω ) .$$

Approximation factors that are multiplied by inverse powers of \sqrt{n}, e.g., functions

$${G}_{i}^{s}$$

for ϵ{0, ½, 1}, associated to [symbol] may be respectively represented by

$${G}_{i}^{s} ( v ) ,$$

which may be associated with a piecewise polynomial

$${\hat{G}}_{i}^{s} ( v ) .$$

In some aspects, using piecewise polynomial approximation may provide several advantages. For example, evaluation computations may be relatively easy (e.g., addition and multiplication are involved). Further, polynomials may be easily described (e.g., only polynomials coefficients and the corresponding degrees need be stored). The piecewise polynomial approximation may be associated with addition and multiplication polynomial evaluation computations. The polynomial coefficients and corresponding degrees associated with piecewise polynomials may be stored in a memory of the transmitter device.

In some aspects, an interval may be a unified interval across multiple approximation terms. The interval includes a first interval associated with the first alphabet [symbol] . The first interval may be a disjoint union of subintervals. Each subinterval of the first interval may be associated with: one reference point, one or more approximation region indices and/or one or more additional indices, one or more polynomial coefficient indices where each polynomial coefficient index may be associated with an approximation region index, one or more multiplication indices where each multiplication index may be associated with a polynomial coefficient index, and one or more type indicators where each type indicator may be associated with the polynomial coefficient index. The interval may be a first additional interval associated with the first alphabet [symbol] . The first additional interval may be a disjoint union of subintervals. Each subinterval of the first additional interval may be associated with: one reference point, one or more approximation region indices, one or more polynomial coefficient indices where each polynomial coefficient index may be associated with an approximation region index, and one or more multiplication indices where each multiplication index may be associated with a polynomial coefficient index.

In some aspects, regarding interval structures, unified intervals may be across multiple approximation terms. The first interval [symbol] =[0, ω^{u}] may be associated with [symbol] . The first interval [symbol] may be a disjoint union of Jₘ subintervals that are ordered and denoted by Lᵢ for i ϵ{1, 2, . . . , jₘ}. Each subinterval of the first interval may be associated with: one reference point, one or more approximation region indices and/or the one or more additional indices, one or more polynomial coefficient indices, each of which may be associated with an approximation region index, one or more multiplication indices, each of which may be associated with a polynomial coefficient index, and one or more type indicators, each of which may be associated with a polynomial coefficient index. The first additional interval

$${𝒥}_{m}^{′} = [ - {v}_{min} , 0 ]$$

may be associated with [symbol] . The first additional interval [symbol] may be a disjoint union of

$${j}_{m}^{′}$$

subintervals that are ordered and denoted by

$${L}_{i}^{′}$$

for i ϵ{1, 2, . . . ,

$${j}_{m}^{′} \} .$$

Each subinterval of the first additional interval may be associated with: one reference point, one or more approximation region indices, one or more polynomial coefficient indices, each of which may be associated with an approximation region index, and one or more multiplication indices, each of which may be associated with a polynomial coefficient index.

FIGS. 11A and 11B are diagrams illustrating examples 1100 associated with a first interval structure, in accordance with the present disclosure.

In some aspects, the first interval may be a disjoint union of a plurality of subintervals. The first interval may be based at least in part on the first alphabet [symbol] . Each subinterval, of the plurality of subintervals of the first interval, may be associated with one or more respective approximation indices. Each one of the one or more respective approximation region indices may be associated with a respective reference point of a plurality of reference points, a respective additional indices, and/or one or more respective polynomial coefficient indices, where each polynomial coefficient index, of the one or more respective polynomial coefficient indices, may be associated with a respective multiplication index of a plurality of multiplication indices and a respective type indicator of a plurality of type indicators. Additionally, each approximation region index of each respective subinterval, of the plurality of subintervals, may be associated with a respective minimum integer and a respective maximum integer, the respective minimum integer and the respective maximum integer indicating a respective range of integers, where each integer, of the respective range of integers, is larger than or equal to the respective minimum integer and smaller than or equal to the respective maximum integer.

As shown in FIG. 11A, ωu is

$$\frac{320}{128}$$

(which equals 2.5). The first interval is [0, 2.5). A subinterval [11/128, 22/128), of the plurality of subintervals of the first interval, is associated with an approximation region index (associated with [symbol] ). The approximation region index associated to the subinterval [11/128, 22/128) may be associated with a reference point a₁, a value of a₁ being 30/128. The approximation region index may be associated with a first polynomial index (Poly-IDX1 for H^{sat}), the first polynomial index being associated with a first multiplication index (Mul-IDX1) and a first type indicator (TYPE-a). The approximation region index may be associated with a second polynomial index (Poly-IDX2 for

$${G}_{0}^{c} ) ,$$

the second polynomial index being associated with a third multiplication index (Mul-IDX3) and a second type indicator (TYPE-b). The approximation region index may be associated with a third polynomial index (Poly-IDX3 for

$${G}_{1}^{c} ) ,$$

the third polynomial index being associated with a fifth multiplication index (Mul-IDX5) and a third type indicator (TYPE-c). The approximation region index may be associated with a fourth polynomial index (Poly-IDX4 for

$${G}_{2}^{c} ) ,$$

the fourth polynomial index being associated with a sixth multiplication index (Mul-IDX6). Additionally, the approximation region index (associated with [symbol] ) of the subinterval [11/128, 22/128) may be associated with a minimum integer and a maximum integer. For example, the minimum integer may be equal to 11 and the maximum integer may be equal to 31.

In some aspects, after a subinterval is located, multiple approximation region indices may still be available. The approximation form to select may depend on the first sequence length n. In other words, each approximation region index may be associated with a minimum n and a maximum n, such that the first sequence n belonging to a particular range may determine which approximation form to use.

The subinterval [11/128, 22/128), of the plurality of subintervals of the first interval, is associated with an approximation region index (associated with [symbol] ). The approximation region index associated to the subinterval [11/128, 22/128) may be associated with the reference point a₁. The approximation region index may be associated with the first polynomial index (Poly-IDX1 for H^{sat}), the first polynomial index being associated with the first multiplication index (Mul-IDX1) and the first type indicator (TYPE-a). The approximation region index may be associated with the second polynomial index (Poly-IDX2 for

$${G}_{0}^{c} ) ,$$

the second polynomial index being associated with the third multiplication index (Mul-IDX3) and the second type indication (TYPE-b). The approximation region index may be associated with the third polynomial index (Poly-IDX3 for

$${G}_{1}^{c} ) ,$$

the third polynomial index being associated with the fifth multiplication index (Mul-IDX5) and the second type indicator (TYPE-c). Additionally, the approximation region index (associated with [symbol] ) of the subinterval [11/128, 22/128) may be associated with a minimum integer an a maximum integer. For example, the minimum integer may be equal to 32 and the maximum integer may be equal to 1024.

A subinterval [109/128, 132/128), of the plurality of subintervals of the first interval, is associated with an approximation region index (associated with [symbol] ). The approximation region index associated to the subinterval [109/128, 132/128) may be associated with a reference point a₂, a value of a₂ being 90/128. The approximation region index may be associated with a fifth polynomial index (Poly-IDX5 for H^{sat}), the fifth polynomial index being associated with the first multiplication index (Mul-IDX1). The approximation region index may be associated with a sixth polynomial index (Poly-IDX6 for

$${G}_{0}^{c} ) ,$$

the sixth polynomial index being associated with the third multiplication index (Mul-IDX3). The approximation region index may be associated with a seventh polynomial index (Poly-IDX7 for

$${G}_{1}^{c} ) ,$$

the seventh polynomial index being associated with the fifth multiplication index (Mul-IDX5). The approximation region index may be associated with an eighth polynomial index (Poly-IDX8 for

$${G}_{2}^{c} ) ,$$

the eighth polynomial index being associated with a sixth multiplication index (Mul-IDX6). Additionally, the approximation region index (associated with [symbol] ) of the subinterval [109/128, 132/128) may be associated with a minimum integer and a maximum integer. For example, the minimum integer may be equal to 11 and the maximum integer may be equal to 31.

Similarly, an approximation region index (associated with [symbol] ), an approximation region index (associated with [symbol] ), and an approximation region index (associated with [symbol] ) may be associated with the reference point a₂ and various polynomial indices and multiplication indices, as shown in FIG. 11A. The approximation region index (associated with [symbol] ) may be associated with a minimum integer and a maximum integer. For example, the minimum integer may be equal to 32 and the maximum integer may be equal to 127. The approximation region index (associated with [symbol] ) may be associated with a minimum integer and a maximum integer. For example, the minimum integer may be equal to 127 and the maximum integer may be equal to 511. The approximation region index (associated with [symbol] ) may be associated with a minimum integer and a maximum integer. For example, the minimum integer may be equal to 512 and the maximum integer may be equal to 1024.

In some aspects, regarding the multiplication indices, Mul-IDX1 may be associated with n (e.g., a multiplication index Mul-IDX1 indicates that the first sequence length n will be multiplied by the corresponding polynomial approximation), Mul-IDX2 may be associated with log n (e.g., a multiplication index Mul-IDX2 indicates that the logarithm of the first sequence length n will be multiplied by the corresponding polynomial approximation), Mul-IDX3 may be associated with 1 (e.g., a multiplication index Mul-IDX3 indicates that 1 will be multiplied by the corresponding polynomial approximation), Mul-IDX4 may be associated with 1/\sqrt{n}, (e.g., a multiplication index Mul-IDX4 indicates that 1/\sqrt{n} will be multiplied by the corresponding polynomial approximation), Mul-IDX5 may be associated with 1/n (e.g., a multiplication index Mul-IDX5 indicates that 1/n will be multiplied by the corresponding polynomial approximation), and Mul-IDX6 may be associated with 1/n² (e.g., a multiplication index Mul-IDX6 indicates that 1/n² will be multiplied by the corresponding polynomial approximation).

As shown in FIG. 11B, a subinterval [272/128, 320/128), of the plurality of subintervals of the first interval, is associated with an approximation region index (associated with [symbol] ). The approximation region index associated to the subinterval [272/128, 320/128) may be associated with a reference point a₄, a value of a₄ being 229/128. The approximation region index may be associated with a fifteenth polynomial index (Poly-IDX15 for H^{sat}), the fifteenth polynomial index being associated with a first multiplication index (Mul-IDX1). The approximation region index may be associated with a sixteenth polynomial index (Poly-IDX16 for

$${G}_{0}^{c} ) ,$$

the sixteenth polynomial index being associated with a third multiplication index (Mul-IDX3). The approximation region index may be associated with a seventeenth polynomial index (Poly-IDX17 for

$${G}_{1}^{c} ) ,$$

the seventeenth polynomial index being associated with a fifth multiplication index (Mul-IDX5). Additionally, the approximation region index (associated with [symbol] ) of the subinterval [272/128, 320/128) may be associated with a minimum integer and a maximum integer. For example, the minimum integer may be equal to 11 and the maximum integer may be equal to 255.

Similarly, an approximation region index (associated with [symbol] ) and an approximation region index (associated with [symbol] ) may be associated with reference point a₄ and various polynomial indices and multiplication indices, as shown in FIG. 11B. The approximation region index (associated with [symbol] ) may be associated with a minimum integer and a maximum integer. For example, the minimum integer may be equal to 256 and the maximum integer may be equal to 511. The approximation region index (associated with [symbol] ) may be associated with a minimum integer and a maximum integer. For example, the minimum integer may be equal to 512 and the maximum integer may be equal to 1024.

In some aspects, when an additional index is T, then the first additional interval [symbol] , may be used to determine polynomials for

$${G}_{i}^{s}$$

for i ϵ{0, ½, 1}, which may be because the approximation forms for [symbol] , [symbol] and [symbol] may consist of one or more

$${G}_{i}^{s}$$

as approximation factors. Further, each polynomial evaluation may be with respect to a reference point.

As indicated above, FIGS. 11A and 11B are provided as examples. Other examples may differ from what is described with regard to FIGS. 11A and 11B.

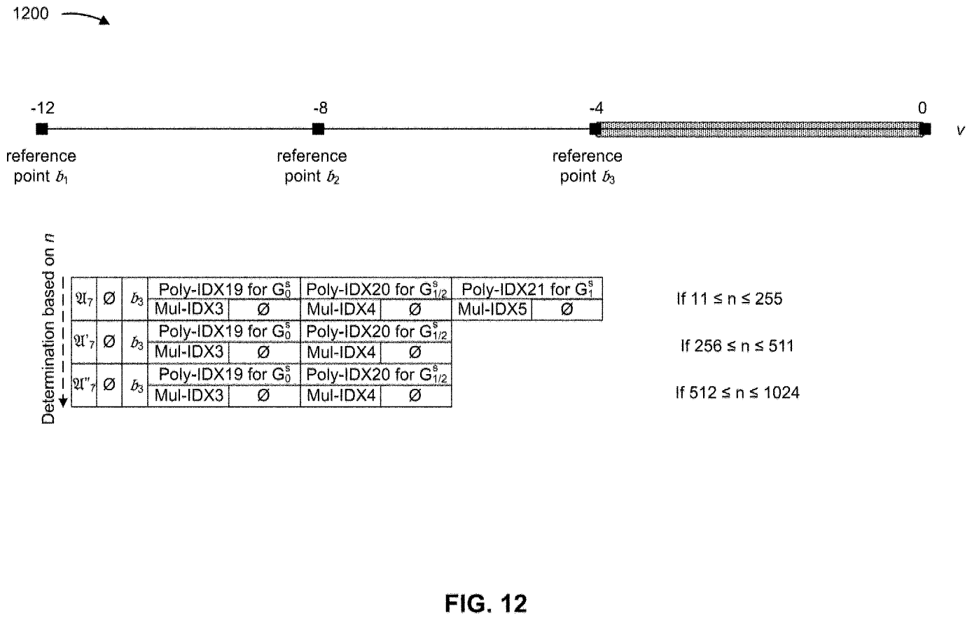

FIG. 12 is a diagram illustrating an example 1200 associated with a first additional interval structure, in accordance with the present disclosure.

In some aspects, the first additional interval may be a disjoint union of a plurality of subintervals. The first additional interval may be based at least in part on the first alphabet [symbol] . Each subinterval, of the plurality of subintervals of the first additional interval, may be associated with one or more respective approximation indices. Each one of the one or more respective approximation region indices may be associated with a respective reference point of a plurality of reference points, a respective additional indices, and/or one or more respective polynomial coefficient indices, where each polynomial coefficient index, of the one or more respective polynomial coefficient indices, may be associated with a respective multiplication index of a plurality of multiplication indices and a respective type indicator of a plurality of type indicators. Additionally, each approximation region index of each respective subinterval, of the plurality of subintervals, may be associated with a respective minimum integer and a respective maximum integer, the respective minimum integer and the respective maximum integer indicating a respective range of integers, where each integer, of the respective range of integers, is larger than or equal to the respective minimum integer and smaller than or equal to the respective maximum integer.

In some aspects, each polynomial coefficient index may indicate an index to a lookup table in which polynomial coefficients are stored. A plurality of polynomials may be associated with a common maximum degree.

As shown in FIG. 12, a subinterval [−4, 0), of the plurality of subintervals of the first additional interval, is associated with an approximation region index (associated with [symbol] ). The approximation region index associated to the subinterval [−4, 0) may be associated with a reference point b₃, a value of b₃ being −4. The approximation region index may be associated with a nineteenth polynomial index (Poly-IDX19 for

$${G}_{0}^{s} ) ,$$

the nineteenth polynomial index being associated with a third multiplication index (Mul-IDX3). The approximation region index may be associated with a twentieth polynomial index (Poly-IDX20 for

$${G}_{1 / 2}^{s} ) ,$$

the twentieth polynomial index being associated with a fourth multiplication index (Mul-IDX4). The approximation region index may be associated with a twenty first polynomial index (Poly-IDX21 for

$${G}_{1}^{s} ) ,$$

the twenty first polynomial index being associated with a fifth multiplication index (Mul-IDX5). Additionally, the approximation region index (associated with [symbol] ) of the subinterval [−4, 0) may be associated with a minimum integer and a maximum integer. For example, the minimum integer may be equal to 11 and the maximum integer may be equal to 255.

Similarly, an approximation region index (associated with [symbol] ) and an approximation region index (associated with [symbol] ) may be associated with the reference point b₃ and various polynomial indices and multiplication indices, as shown in FIG. 12. The approximation region index (associated with [symbol] ) may be associated with a minimum integer and a maximum integer. For example, the minimum integer may be equal to 256 and the maximum integer may be equal to 511. The approximation region index (associated with [symbol] ) may be associated with a minimum integer and a maximum integer. For example, the minimum integer may be equal to 512 and the maximum integer may be equal to 1024.

As indicated above, FIG. 12 is provided as an example. Other examples may differ from what is described with regard to FIG. 12.

In some aspects, an interval may be a unified interval across multiple approximation terms. The interval may be a second interval associated with the first alphabet [symbol] . The second interval may be a disjoint union of subintervals. Each subinterval of the second interval may be associated with: one reference point, one or more approximation region indices, one or more polynomial coefficient indices, where each polynomial coefficient index may be associated with an approximation region index, and one or more multiplication indices. The reference point may be a subinterval boundary point of the interval. The polynomial evaluation may be based at least in part on a polynomial of a difference between the normalized energy ω and the reference point. The subinterval boundary point may be a dyadic number.

In some aspects, regarding interval structures, unified intervals may be across multiple approximation terms. The second interval [symbol] =[0, vₘₐₓ] may be associated with [symbol] . The second interval [symbol] may be a disjoint union of Jₘ subintervals that are ordered and denoted by Rᵢ for i ϵ{1, 2, . . . , Jₘ}, in accordance with:

$$\text{?} = \text{?} {R}_{i} .$$

Each subinterval of the second interval may be associated with: one reference point, one or more approximation region indices, one or more polynomial coefficient indices, each of which may be associated with an approximation region index, and one or more multiplication indices, each of which may be associated with a polynomial coefficient index.

In some aspects, regarding reference points and interval boundaries, a reference point may be a subinterval boundary point of the first interval or the first additional interval or the second interval. Each polynomial evaluation may be with respect to a reference point. For example,

$${\hat{H}}^{s a t} ( ω ) = {\sum }_{i = 1}^{d} {{c}_{i} ( ω - \text{?} )}^{i} ,$$

where d is a polynomial degree, cᵢ is a polynomial coefficient, and a₄ is a reference point. In other words, the polynomial evaluation may involve the polynomial of the difference between the normalized energy ω and the reference point. Further, all subinterval boundaries may be dyadic numbers, e.g., of the form a/2^{l} for some integers a and l.

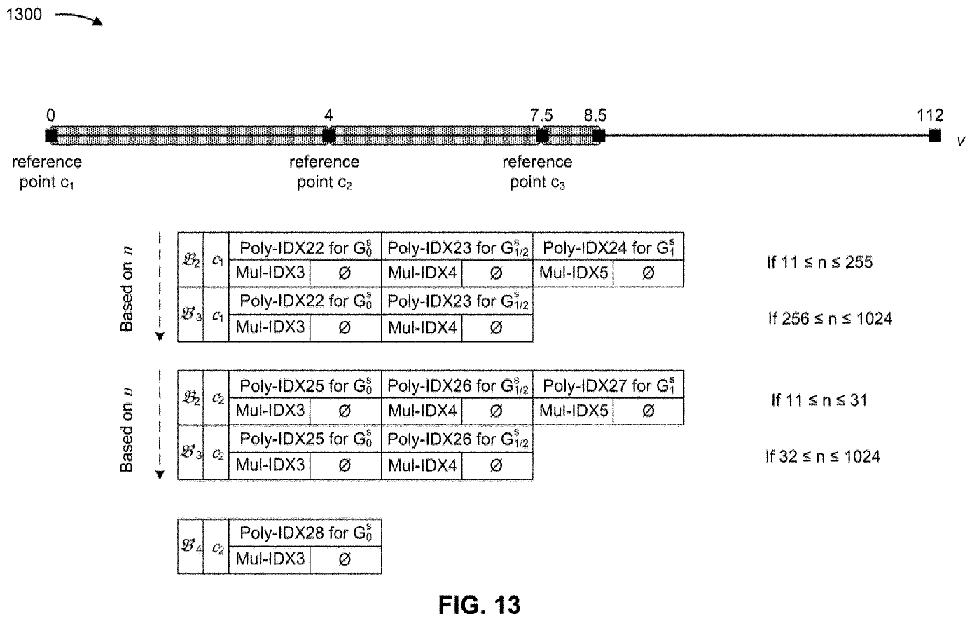

FIG. 13 is a diagram illustrating an example 1300 associated with a second interval structure, in accordance with the present disclosure.

In some aspects, the second interval may be a disjoint union of a plurality of subintervals. The second interval may be based at least in part on the first alphabet [symbol] . Each subinterval, of the plurality of subintervals of the second interval, may be associated with one or more respective approximation indices. Each one of the one or more respective approximation region indices may be associated with a respective reference point of a plurality of reference points, a respective additional indices, and/or one or more respective polynomial coefficient indices, where each polynomial coefficient index, of the one or more respective polynomial coefficient indices, may be associated with a respective multiplication index of a plurality of multiplication indices and a respective type indicator of a plurality of type indicators. Additionally, each approximation region index of each respective subinterval, of the plurality of subintervals of the second interval, may be associated with a respective minimum integer and a respective maximum integer, the respective minimum integer and the respective maximum integer indicating a respective range of integers, where each integer, of the respective range of integers, is larger than or equal to the respective minimum integer and smaller than or equal to the respective maximum integer.

As shown in FIG. 13, a subinterval [0, 4), of the plurality of subintervals of the second interval, is associated with an approximation region index (associated with [symbol] ). The approximation region index (associated with [symbol] ) of the subinterval [0, 4) may be associated with a reference point c₁, a value of c₁ being 0. The approximation region index (associated with [symbol] ) may be associated with a twenty second polynomial index (Poly-IDX22 for

$${G}_{0}^{s} ) ,$$

the twenty second polynomial index being associated with a third multiplication index (Mul-IDX3). The approximation region index (associated with [symbol] ) may be associated with a twenty third polynomial index (Poly-IDX23 for

$${G}_{1 / 2}^{s} ) ,$$

the twenty third polynomial index being associated with a fourth multiplication index (Mul-IDX4). The approximation region index (associated with [symbol] ) may be associated with a twenty fourth polynomial index (Poly-IDX24 for

$${G}_{1}^{s} ) ,$$

the twenty fourth polynomial index being associated with a fifth multiplication index (Mul-IDX5). Additionally, the approximation region index (associated with [symbol] ) of the subinterval [0, 4) may be associated with a minimum integer and a maximum integer. For example, the minimum integer may be equal to 11 and the maximum integer may be equal to 255. Similarly, the subinterval [0, 4) may be associated with an approximation region index (associated with [symbol] ). The approximation region index (associated with [symbol] ) of the subinterval [0, 4) may be associated with the reference point c₁. Additionally, the approximation region index (associated with [symbol] ) of the subinterval [0, 4) may be associated with a minimum integer and a maximum integer. For example, the minimum integer may be equal to 256 and the maximum integer may be equal to 1024, as shown in FIG. 12.

As shown in FIG. 13, a subinterval [4, 7.5), of the plurality of subintervals of the second interval, is associated with the approximation region index (associated with [symbol] ). The approximation region index (associated with [symbol] ) of the subinterval [4, 7.5) may be associated with a reference point c₂, a value of c₂ being 4. The approximation region index (associated with [symbol] ) may be associated with a twenty fifth polynomial index (Poly-IDX25 for

$${G}_{0}^{s} ) ,$$

the twenty fifth polynomial index being associated with a third multiplication index (Mul-IDX3). The approximation region index (associated with [symbol] ) may be associated with a twenty sixth polynomial index (Poly-IDX26 for

$${G}_{1 / 2}^{s} ) ,$$

the twenty sixth polynomial index being associated with a fourth multiplication index (Mul-IDX4). The approximation region index (associated with [symbol] ) may be associated with a twenty seventh polynomial index (Poly-IDX27 for

$${G}_{1}^{s} ) ,$$

the twenty seventh polynomial index being associated with a fifth multiplication index (Mul-IDX5). Additionally, the approximation region index (associated with [symbol] ) of the subinterval [4, 7.5) may be associated with a minimum integer and a maximum integer. For example, the minimum integer may be equal to 11 and the maximum integer may be equal to 31. Similarly, the subinterval [4, 7.5) may be associated with an approximation region index (associated with [symbol] ). The approximation region index (associated with [symbol] ) of the subinterval [4, 7.5) may be associated with the reference point c₂. Additionally, the approximation region index (associated with [symbol] ) of the subinterval [4, 7.5) may be associated with a minimum integer and a maximum integer. For example, the minimum integer may be equal to 32 and the maximum integer may be equal to 1024.

As shown in FIG. 13, a subinterval [7.5, 8.5), of the plurality of subintervals of the second interval, is associated with an approximation region index (associated with [symbol] ). The approximation region index (associated with [symbol] ) of the subinterval [7.5, 8.5) may be associated with a reference point c₃, a value of c₃ being 7.5. The approximation region index (associated with [symbol] ) may be associated with a twenty eighth polynomial index (Poly-IDX28 for

$${G}_{0}^{s} ) ,$$

the twenty eighth polynomial index being associated with a third multiplication index (Mul-IDX3).

As indicated above, FIG. 13 is provided as an example. Other examples may differ from what is described with regard to FIG. 13.

In some aspects, a binary search tree structure may be associated with an interval. Subinterval boundaries including reference points may be stored using the binary search tree structure. Each interval node of the binary search tree structure may store one key that corresponds to a subinterval boundary of the subinterval boundaries. Each leaf node of the binary search tree structure may store a subinterval index corresponding to the subinterval. The binary search tree structure may be traversed from a root node to a leaf node to enable a binary search for the subinterval associated with the normalized energy ω or the centralized and scaled energy v.

In some aspects, a search (e.g., an interval search or a subinterval search) may be performed for the polynomial approximation. The binary tree structure may be used for the search. The search may be associated with a binary tree search. A respective binary tree structure may be associated with each of the first interval, the first additional interval, or the second interval. The subinterval boundaries (e.g., including reference points) may be stored using the binary tree structure. Each internal node may store one key that corresponds to the subinterval boundary. The subinterval boundaries may have a special structure, e.g., dyadic numbers. The internal node may be a special node when its associated key is a reference point. Each leaf node may store the subinterval index corresponding to the subinterval. The binary tree structure may be constructed such that traversing the path from the root to the leaf node mimics a binary search for a subinterval, where the normalized energy ω or the centralized and scaled energy v is in the subinterval.

In some aspects, the transmitter device may perform the search, which may be based at least in part on the first alphabet size m. When performing the search, the transmitter device may determine the normalized energy ω. The transmitter device may compare the normalized energy) with a uniform symbol energy ω^{u}. In other words, given n and E, the normalized energy a may be determined and compared with the uniform symbol energy ω^{u}. The transmitter device may determine to start with the binary search tree structure for an interval depending on whether ω−ω^{u}<0, where the interval may be one of a first interval or a second interval. When ω−ω^{u}<0, the binary tree may be started for the first interval. Otherwise, the binary tree may be selected for the second interval. The transmitter device may traverse the binary search tree structure from the root node of the binary search tree structure. The transmitter device may perform a subtraction ω−ω_{key} with a key ω_{key} associated with an internal node. At each internal node, a subtraction ω−ω_{key} may be made with the key ω_{key} associated with that internal node. When the internal node is special, e.g., its key is a reference point, then the difference may be tracked. The transmitter device may move to a left child of the internal node based at least in part on ω−ω_{key}<0 or move to a right child of the internal node based at least in part on ω−ω_{key}≥0. In other words, when ω−ω_{key}<0, the search may involve going to the left child of the internal node, and when ω−ω_{key}≥0, the search may involve going to the right child of the internal node. The transmitter device may determine, after reaching the leaf node of the binary search tree structure, a subinterval index stored at the leaf node and a most recent difference ω−ω_{ref}, where ω_{ref} is the most recently visited reference point along the path traversed from the root node to the leaf node. After the subinterval index is found, a corresponding subinterval may be associated with more than one approximation region indices. In these cases, the first sequence length n may be used to determine which approximation region index to select. In other words, based at least in part on the subinterval index, the approximation region index may be determined based at least in part on the first sequence length n and the identifying of the subinterval index. After determining the approximation region index, earlier described procedures may be applied.

FIG. 14 is a diagram illustrating an example 1400 associated with a search, in accordance with the present disclosure.

As shown in FIG. 14, a search with m=4 may involve one or more of a reference point a₁, a reference point a₂, a reference point a₃, or a reference point a₄. A binary tree, from which the search is performed, may be associated with the reference point a₁, the reference point a₂, the reference point a₃, and the reference point a₄. In this example, after the search, a difference ω−a₄ and a subinterval index 14 may be available.

As indicated above, FIG. 14 is provided as an example. Other examples may differ from what is described with regard to FIG. 14.

In some aspects, polynomial coefficients may be stored in one or more lookup tables based at least in part on a fixed ROM storage. The polynomial coefficient indices may be used for table lookups. A row of the lookup table may correspond to the polynomial coefficients corresponding to a polynomial index of a subinterval. Each column of the lookup table may correspond to a power of a most recent difference ω−ω_{ref}. In some aspects, the storage of the polynomial coefficients may be based at least in part on the fixed ROM storage, which may be independent of n. Regarding the storage of polynomial coefficients, one or more lookup tables may be used to store the polynomial coefficients. The polynomial indices may be used for table lookups. The polynomial coefficients may be stored in different forms depending on implementation (e.g., a truncated precision of real-valued coefficients or dyadic number approximation).

FIG. 15 is a diagram illustrating an example 1500 associated with a look-up table for storage of polynomial coefficients, in accordance with the present disclosure.

As shown in FIG. 15, a look-up table may be composed of a number of rows and a number of columns (e.g., five rows and four columns). Each row may correspond to the polynomial coefficients corresponding to a polynomial index of some subinterval. For example, a particular row may correspond to the polynomial:

$${p}_{3} ( ω ) = {\sum }_{j = 0}^{3} {{c}_{j}^{( 3 )} ( ω - {ω}_{r e f} )}^{j} .$$

Further, each column may correspond to a power of ω−ω_{ref}.

As indicated above, FIG. 15 is provided as an example. Other examples may differ from what is described with regard to FIG. 15.

In some aspects, a characteristic term for H^{sat} may involve a singularity in H^{sat} for a relatively small ω. A special term may be added to the polynomial approximation of H^{sat}. When the type indicator is TYPE-a, then an approximation of H^{sat} denoted by Ĥ^{sat}, may be determined as: Ĥ^{sat}(ω)=L_{H}(ω)−ω log ω. Here, L_{H} may correspond to a polynomial approximation for H^{sat}. In some aspects, regarding an implementation of ω log ω, since ω=E/n, the following may be derived:

$$ω log ω = \frac{E}{n} log \frac{E}{n} = \frac{E}{n} ( log E - log n ) .$$

An approximation for nH^{sat}(ω) may be nĤ^{sat}(ω), which may be equal to:

$$n {\hat{H}}^{s a t} ( ω ) = n {L}_{H} ( ω ) - E ( log E - log n ) .$$

In other words, the approximation may involve a multiplication of the first sequence energy E and a difference between a logarithm of the first sequence energy E and a logarithm of the first sequence length n, e.g., E(log E−log n) is subtracted from nL_{H}(ω).

In some aspects, a characteristic term for

$${G}_{0}^{c} and {G}_{1}^{c}$$

may involve a singularity in

$${G}_{0}^{c} and {G}_{1}^{c}$$

for a relatively small ω. A special term may be added to the polynomial approximation for

$${G}_{0}^{c} .$$

An approximation factor

$${G}_{0}^{c} ( ω )$$

may be associated with a type indicator, where the approximation factor

$${G}_{0}^{c} ( ω )$$

may be associated with an approximation region. When the type indicator is TYPE-b, then an approximation of

$${G}_{0}^{c} ,$$

denoted by

$${\hat{G}}_{0}^{c} ,$$

may be determined as:

$${\hat{G}}_{0}^{c} ( ω ) = {L}_{{G}_{0}^{c}} ( ω ) - \frac{1}{2} log ω .$$

### Here,

$${L}_{{G}_{0}^{c}}$$

may correspond to a polynomial approximation for

$${G}_{0}^{c} .$$

In some aspects, a special term may be added to the polynomial approximation for

$${G}_{1}^{c} .$$

An approximation factor

$${G}_{1}^{c} ( ω )$$

may be associated with a type indicator, where the approximation factor

$${G}_{1}^{c} ( ω )$$

may be associated with an approximation region. When the type indicator is TYPE-c, then an approximation of

$${G}_{1}^{c} ,$$

denoted by

$${\hat{G}}_{1}^{c} ,$$

may be determined as:

$${\hat{G}}_{1}^{c} ( ω ) = {L}_{{G}_{1}^{c}} ( ω ) - \frac{1}{12 ω} .$$

### Here,

$${L}_{{G}_{1}^{c}}$$

way correspond to a polynomial approximation for

$${G}_{1}^{c} .$$

In some aspects, regarding an implementation of −½ log ω and −1/(12ω), since E=ωn, an approximation for

$${G}_{0}^{c} ( ω )$$

may be

$${\hat{G}}_{0}^{c} ( ω ) ,$$

which may be equal to:

$${\hat{G}}_{0}^{c} ( ω ) = {L}_{{G}_{0}^{c}} ( ω ) - \frac{1}{2} ( log E - log n ) .$$

Since E=ωn, an approximation for

$${G}_{1}^{c} ( ω ) / n$$

may be

$${\hat{G}}_{1}^{c} ( ω ) / n ,$$

which may be equal to:

$$\frac{1}{n} {\hat{G}}_{1}^{c} ( ω ) = \frac{1}{n} {L}_{{G}_{1}^{c}} ( ω ) - \frac{1}{12 E} .$$

In some aspects, c(E) may be a function of energy variable E. The function c may not depend on the first alphabet [symbol] , and may be used when the first sequence energy E satisfies a threshold. The term c(E) may only be used for a relatively small (e.g., a very small) E (e.g., [symbol] or [symbol] ). When the logarithm of the approximation is under base e, the approximation may have the following parametric form as a function of E:

$$c ( E ) = {log}_{e} \frac{\sqrt{2 π} {E}^{E + \frac{1}{2}} {e}^{- E} {e}^{\frac{1}{12 E}}}{E !} .$$

The values of c(E) may be (approximately) tabulated. The function c of the first sequence energy E (c(E)) may be approximately tabled for a plurality of first sequence energy E values. For example, when E ranges between 1 and 7, values of E may be associated with values of c(E), respectively. In this example, E=1 may be associated with c(E)≈2.2719×10⁻³, E=2 may be associated with c(E)≈3.2597×10⁻⁴, E=3 may be associated with c(E)≈9.9852×10⁻⁵, E=4 may be associated with c(E)≈4.2661×10⁻⁵, E=5 may be associated with c(E)≈2.1975×10⁻⁵, E=6 may be associated with c(E)≈1.2760×10⁻⁵, and E=7 may be associated with c(E)≈8.0520×10⁻⁶.

FIG. 16 is a diagram illustrating an example process 1600 performed, for example, by a transmitter device, in accordance with the present disclosure. Example process 1600 is an example where the transmitter device (e.g., UE 120 or network node 110) performs operations associated with polynomial approximation techniques for probabilistic amplitude shaping.

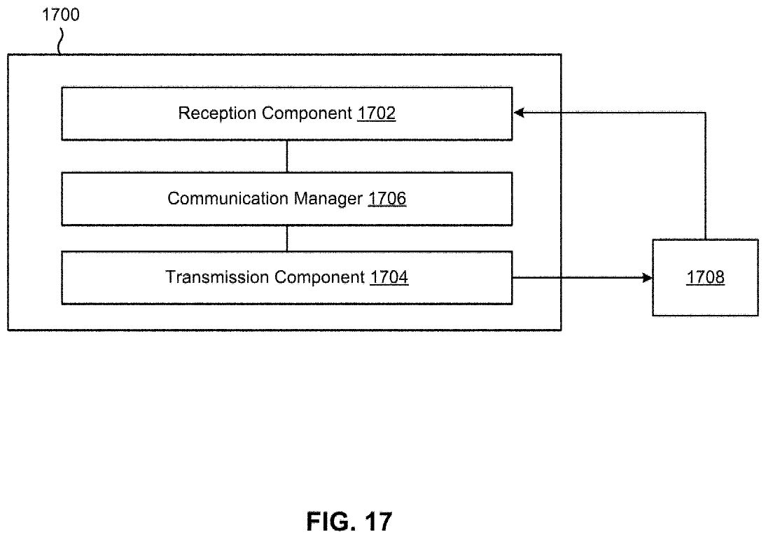

As shown in FIG. 16, in some aspects, process 1600 may include obtaining a plurality of information bits for a probabilistic shaping scheme, the probabilistic shaping scheme being associated with an energy threshold (block 1610). For example, the transmitter device (e.g., using communication manager 1706, depicted in FIG. 17) may obtain a plurality of information bits for a probabilistic shaping scheme, the probabilistic shaping scheme being associated with an energy threshold, as described above.

As further shown in FIG. 16, in some aspects, process 1600 may include forming, as part of the probabilistic shaping scheme, polynomial approximations of a plurality of approximation factors (block 1620). For example, the transmitter device (e.g., using communication manager 1706, depicted in FIG. 17) may form, as part of the probabilistic shaping scheme, polynomial approximations of a plurality of approximation factors, as described above.

As further shown in FIG. 16, in some aspects, process 1600 may include obtaining, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy (block 1630). For example, the transmitter device (e.g., using communication manager 1706, depicted in FIG. 17) may obtain, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy, as described above.

As further shown in FIG. 16, in some aspects, process 1600 may include performing an exponentiation operation on the approximation of the logarithm of the cumulative sequence quantity, thereby obtaining an approximation of the cumulative sequence quantity (block 1640). For example, the transmitter device (e.g., using communication manager 1706, depicted in FIG. 17) may perform an exponentiation operation on the approximation of the logarithm of the cumulative sequence quantity, thereby obtaining an approximation of the cumulative sequence quantity, as described above.

As further shown in FIG. 16, in some aspects, process 1600 may include encoding, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size (block 1650). For example, the transmitter device (e.g., using communication manager 1706, depicted in FIG. 17) may encode, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size, as described above.

As further shown in FIG. 16, in some aspects, process 1600 may include transmitting a message to one or more receiver devices based at least in part on the symbol sequence (block 1660). For example, the transmitter device (e.g., using transmission component 1704 and/or communication manager 1706, depicted in FIG. 17) may transmit a message to one or more receiver devices based at least in part on the symbol sequence, as described above.

Process 1600 may include additional aspects, such as any single aspect or any combination of aspects described below and/or in connection with one or more other processes described elsewhere herein.

In a first aspect, process 1600 includes determining a normalized energy corresponding to a ratio between the first sequence energy and the first sequence length, obtaining a uniform energy, the uniform energy being associated with the first alphabet, obtaining a subinterval of an interval based at least in part on the normalized energy, and utilizing the subinterval of the interval and the normalized energy to form at least one of the polynomial approximations of the plurality of approximation factors.

In a second aspect, alone or in combination with the first aspect, at least one of the interval is associated with the first alphabet, the interval comprises a plurality of subintervals, and the interval corresponds to a disjoint union of the plurality of subintervals, or each subinterval, of the plurality of subintervals of the interval, corresponds to a respective left subinterval boundary of a plurality of left subinterval boundaries.

In a third aspect, alone or in combination with one or more of the first and second aspects, each subinterval, of the plurality of subintervals of the interval, is associated with one or more respective approximation region indices, each one of the one or more respective approximation region indices being associated with at least one of a respective reference point of a plurality of reference points, a respective additional indices, or one or more respective polynomial coefficient indices, each polynomial coefficient index, of the one or more respective polynomial coefficient indices, being associated with a respective multiplication index of a plurality of multiplication indices and a respective type indicator of a plurality of type indicators.

In a fourth aspect, alone or in combination with one or more of the first through third aspects, at least one of one or more reference points of the plurality of reference points correspond to dyadic numbers, one or more left subinterval boundaries of the plurality of subintervals of the interval correspond to dyadic numbers, one or more reference points of the plurality of reference points coincide with one or more respective left subinterval boundaries of the plurality of left subinterval boundaries, or a total number of reference points of the plurality of reference points is smaller than a total number of left subinterval boundaries of the plurality of subintervals of the interval.

In a fifth aspect, alone or in combination with one or more of the first through fourth aspects, the plurality of left subinterval boundaries is stored as a binary tree structure having a root node, a plurality of internal nodes, and a plurality of leaf nodes, each internal node, of the plurality of internal nodes, stores one key that corresponds to a respective left subinterval boundary, and each leaf node, of the plurality of leaf nodes, stores one subinterval index that corresponds to a respective subinterval of the plurality of subintervals of the interval.

In a sixth aspect, alone or in combination with one or more of the first through fifth aspects, process 1600 includes performing a binary search by traversing a path of the binary tree structure from the root node to a leaf node of the plurality of leaf nodes, wherein the leaf node, of the plurality of leaf nodes, stores a subinterval index that corresponds to the subinterval of the interval, identifying the subinterval of the interval based at least in part on the subinterval index, determining an approximation region index based at least in part on the first sequence length and the identifying of the subinterval of the interval, identifying one or more polynomial coefficient indices, the one or more polynomial coefficient indices being associated with the approximation region index, identifying a respective multiplication index for each polynomial coefficient index of the one or more polynomial coefficient indices, and identifying a respective type indicator for each polynomial coefficient index of the one or more polynomial coefficient indices.

In a seventh aspect, alone or in combination with one or more of the first through sixth aspects, process 1600 includes determining a difference between the normalized energy and a reference point corresponding to the subinterval of the interval, or determining a difference between a centralized and scaled energy and a reference point corresponding to the subinterval of the interval, wherein the centralized and scaled energy corresponds to a square root of the first sequence length multiplying a difference between the normalized energy and the uniform energy.

In an eighth aspect, alone or in combination with one or more of the first through seventh aspects, process 1600 includes computing one or more polynomial values, each polynomial value, of the one or more polynomial values, corresponding to a respective polynomial coefficient index of the one or more polynomial coefficient indices, determining one or more multiplication factors, each multiplication factor, of the one or more multiplication factors, being based at least in part on a multiplication index being associated to a respective polynomial coefficient index of the one or more polynomial coefficient indices, and determining one or more approximation terms, each approximation term, of the one or more approximation terms, being based at least in part on a multiplication of a respective polynomial value, of the one or more polynomial values, and a respective multiplication factor, of the one or more multiplication factors.

In a ninth aspect, alone or in combination with one or more of the first through eighth aspects, each respective polynomial approximation is based at least in part on a plurality of polynomial coefficients and a polynomial degree, the plurality of polynomial coefficients and the polynomial degree being stored in a memory of the transmitter device.

In a tenth aspect, alone or in combination with one or more of the first through ninth aspects, the plurality of polynomial coefficients is stored in a lookup table.

In an eleventh aspect, alone or in combination with one or more of the first through tenth aspects, process 1600 includes determining an approximation region based at least in part on the first sequence length and the first sequence energy, the approximation region being associated with the first alphabet, identifying an approximation form that corresponds to the approximation region, wherein forming the polynomial approximations of the plurality of approximation factors is based at least in part on the identifying of the approximation form.

In a twelfth aspect, alone or in combination with one or more of the first through eleventh aspects, the cumulative sequence quantity defines a cardinality of a set of all sequences over the first alphabet, each sequence, of the set of all sequences over the first alphabet, having a respective length equal to the first sequence length and a respective energy less than or equal to the first sequence energy.

In a thirteenth aspect, alone or in combination with one or more of the first through twelfth aspects, process 1600 includes multiplying each polynomial approximation, of the polynomial approximations of the plurality of approximation factors, by a respective multiplicative factor, the respective multiplicative factor being based at least in part on the first sequence length, obtaining a plurality of approximation terms based at least in part on the multiplying, each approximation term, of the plurality of approximation terms, corresponds to a respective polynomial approximation of the polynomial approximations of the plurality of approximation factors, and summing the plurality of approximation terms to obtain the approximation of the logarithm of the cumulative sequence quantity.

In a fourteenth aspect, alone or in combination with one or more of the first through thirteenth aspects, the polynomial approximations of the plurality of approximation factors comprise at least one of a first piecewise polynomial approximation of a saturated entropy function of a normalized energy, the saturated entropy function corresponding to a first approximation factor of the plurality of approximation factors, and the saturated entropy function being associated with the first alphabet, or a respective piecewise polynomial approximation corresponding to each of one or more additional functions, each of the one or more additional functions being a function of the normalized energy or a centralized and scaled energy.

In a fifteenth aspect, alone or in combination with one or more of the first through fourteenth aspects, process 1600 includes removing singularities from at least one of the polynomial approximations of the plurality of approximation factors.

In a sixteenth aspect, alone or in combination with one or more of the first through fifteenth aspects, the logarithm, of the cumulative sequence quantity, is under a base of 2, and the performing of the exponentiation operation is under a base of 2.

In a seventeenth aspect, alone or in combination with one or more of the first through sixteenth aspects, at least one of the probabilistic shaping scheme is associated with the second alphabet and the second sequence length, the second alphabet size is greater than 1, or the second alphabet comprises a plurality of amplitude symbols.

In an eighteenth aspect, alone or in combination with one or more of the first through seventeenth aspects, the first alphabet is a subset of or equal to the second alphabet, the first sequence length is less than or equal to the second sequence length, and the first sequence energy is less than or equal to the energy threshold.

In a nineteenth aspect, alone or in combination with one or more of the first through eighteenth aspects, at least one of the second sequence length is a power of 2, or the first sequence length is a power of 2.

In a twentieth aspect, alone or in combination with one or more of the first through nineteenth aspects, the probabilistic shaping scheme and the transmitting are performed by a UE.

In a twenty-first aspect, alone or in combination with one or more of the first through twentieth aspects, the probabilistic shaping scheme and the transmitting are performed by a network node.

Although FIG. 16 shows example blocks of process 1600, in some aspects, process 1600 may include additional blocks, fewer blocks, different blocks, or differently arranged blocks than those depicted in FIG. 16. Additionally, or alternatively, two or more of the blocks of process 1600 may be performed in parallel.

FIG. 17 is a diagram of an example apparatus 1700 for wireless communication, in accordance with the present disclosure. The apparatus 1700 may be a transmitter device, or a transmitter device may include the apparatus 1700. In some aspects, the apparatus 1700 includes a reception component 1702, a transmission component 1704, and/or a communication manager 1706, which may be in communication with one another (for example, via one or more buses and/or one or more other components). In some aspects, the communication manager 1706 is the communication manager 140 or the communication manager 150 described in connection with FIG. 1. As shown, the apparatus 1700 may communicate with another apparatus 1708, such as a UE or a network node (such as a CU, a DU, an RU, or a base station), using the reception component 1702 and the transmission component 1704.

In some aspects, the apparatus 1700 may be configured to perform one or more operations described herein in connection with FIGS. 7, 8A-8B, 9-10, 11A-11B, and 12-15. Additionally, or alternatively, the apparatus 1700 may be configured to perform one or more processes described herein, such as process 1600 of FIG. 16. In some aspects, the apparatus 1700 and/or one or more components shown in FIG. 17 may include one or more components of the transmitter device described in connection with FIG. 2. Additionally, or alternatively, one or more components shown in FIG. 17 may be implemented within one or more components described in connection with FIG. 2. Additionally, or alternatively, one or more components of the set of components may be implemented at least in part as software stored in a memory. For example, a component (or a portion of a component) may be implemented as instructions or code stored in a non-transitory computer-readable medium and executable by a controller or a processor to perform the functions or operations of the component.

The reception component 1702 may receive communications, such as reference signals, control information, data communications, or a combination thereof, from the apparatus 1708. The reception component 1702 may provide received communications to one or more other components of the apparatus 1700. In some aspects, the reception component 1702 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 1700. In some aspects, the reception component 1702 may include one or more antennas, a modem, a demodulator, a MIMO detector, a receive processor, a controller/processor, a memory, or a combination thereof, of the transmitter device described in connection with FIG. 2.

The transmission component 1704 may transmit communications, such as reference signals, control information, data communications, or a combination thereof, to the apparatus 1708. In some aspects, one or more other components of the apparatus 1700 may generate communications and may provide the generated communications to the transmission component 1704 for transmission to the apparatus 1708. In some aspects, the transmission component 1704 may perform signal processing on the generated communications (such as filtering, amplification, modulation, digital-to-analog conversion, multiplexing, interleaving, mapping, or encoding, among other examples), and may transmit the processed signals to the apparatus 1708. In some aspects, the transmission component 1704 may include one or more antennas, a modem, a modulator, a transmit MIMO processor, a transmit processor, a controller/processor, a memory, or a combination thereof, of the transmitter device described in connection with FIG. 2. In some aspects, the transmission component 1704 may be co-located with the reception component 1702 in a transceiver.

The communication manager 1706 may support operations of the reception component 1702 and/or the transmission component 1704. For example, the communication manager 1706 may receive information associated with configuring reception of communications by the reception component 1702 and/or transmission of communications by the transmission component 1704. Additionally, or alternatively, the communication manager 1706 may generate and/or provide control information to the reception component 1702 and/or the transmission component 1704 to control reception and/or transmission of communications.

The communication manager 1706 may obtain a plurality of information bits for a probabilistic shaping scheme, the probabilistic shaping scheme being associated with an energy threshold. The communication manager 1706 may form, as part of the probabilistic shaping scheme, polynomial approximations of a plurality of approximation factors. The communication manager 1706 may obtain, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy. The communication manager 1706 may perform an exponentiation operation on the approximation of the logarithm of the cumulative sequence quantity, thereby obtaining an approximation of the cumulative sequence quantity. The communication manager 1706 may encode, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size. The transmission component 1704 may transmit a message to one or more receiver devices based at least in part on the symbol sequence.

The communication manager 1706 may determine a normalized energy corresponding to a ratio between the first sequence energy and the first sequence length. The communication manager 1706 may obtain a uniform energy, the uniform energy being associated with the first alphabet. The communication manager 1706 may obtain a subinterval of an interval based at least in part on the normalized energy. The communication manager 1706 may utilize the subinterval of the interval and the normalized energy to form at least one of the polynomial approximations of the plurality of approximation factors.

The communication manager 1706 may perform a binary search by traversing a path of the binary tree structure from the root node to a leaf node of the plurality of leaf nodes, wherein the leaf node, of the plurality of leaf nodes, stores a subinterval index that corresponds to the subinterval of the interval. The communication manager 1706 may identify the subinterval of the interval based at least in part on the subinterval index. The communication manager 1706 may determine an approximation region index based at least in part on the first sequence length and the identifying of the subinterval of the interval. The communication manager 1706 may identify one or more polynomial coefficient indices, the one or more polynomial coefficient indices being associated with the approximation region index. The communication manager 1706 may identify a respective multiplication index for each polynomial coefficient index of the one or more polynomial coefficient indices. The communication manager 1706 may identify a respective type indicator for each polynomial coefficient index of the one or more polynomial coefficient indices.

The communication manager 1706 may determine a difference between the normalized energy and a reference point corresponding to the subinterval of the interval. The communication manager 1706 may determine a difference between a centralized and scaled energy and a reference point corresponding to the subinterval of the interval, wherein the centralized and scaled energy corresponds to a square root of the first sequence length multiplying a difference between the normalized energy and the uniform energy.

The communication manager 1706 may compute one or more polynomial values, each polynomial value, of the one or more polynomial values, corresponding to a respective polynomial coefficient index of the one or more polynomial coefficient indices. The communication manager 1706 may determine one or more multiplication factors, each multiplication factor, of the one or more multiplication factors, being based at least in part on a multiplication index being associated to a respective polynomial coefficient index of the one or more polynomial coefficient indices. The communication manager 1706 may determine one or more approximation terms, each approximation term, of the one or more approximation terms, being based at least in part on a multiplication of a respective polynomial value, of the one or more polynomial values, and a respective multiplication factor, of the one or more multiplication factors.

The communication manager 1706 may determine an approximation region based at least in part on the first sequence length and the first sequence energy, the approximation region being associated with the first alphabet. The communication manager 1706 may identify an approximation form that corresponds to the approximation region, wherein forming the polynomial approximations of the plurality of approximation factors is based at least in part on the identifying of the approximation form.

The communication manager 1706 may multiply each polynomial approximation, of the polynomial approximations of the plurality of approximation factors, by a respective multiplicative factor, the respective multiplicative factor being based at least in part on the first sequence length. The communication manager 1706 may obtain a plurality of approximation terms based at least in part on the multiplying, each approximation term, of the plurality of approximation terms, corresponds to a respective polynomial approximation of the polynomial approximations of the plurality of approximation factors. The communication manager 1706 may sum the plurality of approximation terms to obtain the approximation of the logarithm of the cumulative sequence quantity. The communication manager 1706 may remove singularities from at least one of the polynomial approximations of the plurality of approximation factors.

The number and arrangement of components shown in FIG. 17 are provided as an example. In practice, there may be additional components, fewer components, different components, or differently arranged components than those shown in FIG. 17. Furthermore, two or more components shown in FIG. 17 may be implemented within a single component, or a single component shown in FIG. 17 may be implemented as multiple, distributed components. Additionally, or alternatively, a set of (one or more) components shown in FIG. 17 may perform one or more functions described as being performed by another set of components shown in FIG. 17.

The following provides an overview of some Aspects of the present disclosure:

Aspect 1: A method of wireless communication performed by a transmitter device, comprising: obtaining a plurality of information bits for a probabilistic shaping scheme, the probabilistic shaping scheme being associated with an energy threshold; forming, as part of the probabilistic shaping scheme, polynomial approximations of a plurality of approximation factors; obtaining, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy; performing an exponentiation operation on the approximation of the logarithm of the cumulative sequence quantity, thereby obtaining an approximation of the cumulative sequence quantity; encoding, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size; and transmitting a message to one or more receiver devices based at least in part on the symbol sequence.

Aspect 2: The method of Aspect 1, wherein forming the polynomial approximations of the plurality of approximation factors further comprises: determining a normalized energy corresponding to a ratio between the first sequence energy and the first sequence length; obtaining a uniform energy, the uniform energy being associated with the first alphabet; obtaining a subinterval of an interval based at least in part on the normalized energy; and utilizing the subinterval of the interval and the normalized energy to form at least one of the polynomial approximations of the plurality of approximation factors.

Aspect 3: The method of Aspect 2, wherein at least one of: the interval is associated with the first alphabet; the interval comprises a plurality of subintervals, and the interval corresponds to a disjoint union of the plurality of subintervals; or each subinterval, of the plurality of subintervals of the interval, corresponds to a respective left subinterval boundary of a plurality of left subinterval boundaries.

Aspect 4: The method of Aspect 3, wherein each subinterval, of the plurality of subintervals of the interval, is associated with one or more respective approximation region indices, each one of the one or more respective approximation region indices being associated with at least one of: a respective reference point of a plurality of reference points, a respective additional indices, or one or more respective polynomial coefficient indices, each polynomial coefficient index, of the one or more respective polynomial coefficient indices, being associated with a respective multiplication index of a plurality of multiplication indices and a respective type indicator of a plurality of type indicators.

Aspect 5: The method of Aspect 4, wherein at least one of: one or more reference points of the plurality of reference points correspond to dyadic numbers; one or more left subinterval boundaries of the plurality of subintervals of the interval correspond to dyadic numbers; one or more reference points of the plurality of reference points coincide with one or more respective left subinterval boundaries of the plurality of left subinterval boundaries; or a total number of reference points of the plurality of reference points is smaller than a total number of left subinterval boundaries of the plurality of subintervals of the interval.

Aspect 6: The method of Aspect 4, wherein: the plurality of left subinterval boundaries is stored as a binary tree structure having a root node, a plurality of internal nodes, and a plurality of leaf nodes; each internal node, of the plurality of internal nodes, stores one key that corresponds to a respective left subinterval boundary; and each leaf node, of the plurality of leaf nodes, stores one subinterval index that corresponds to a respective subinterval of the plurality of subintervals of the interval.

Aspect 7: The method of Aspect 6, wherein obtaining the subinterval of the interval further comprises: performing a binary search by traversing a path of the binary tree structure from the root node to a leaf node of the plurality of leaf nodes, wherein the leaf node, of the plurality of leaf nodes, stores a subinterval index that corresponds to the subinterval of the interval; identifying the subinterval of the interval based at least in part on the subinterval index; determining an approximation region index based at least in part on the first sequence length and the identifying of the subinterval of the interval; identifying one or more polynomial coefficient indices, the one or more polynomial coefficient indices being associated with the approximation region index; identifying a respective multiplication index for each polynomial coefficient index of the one or more polynomial coefficient indices; and identifying a respective type indicator for each polynomial coefficient index of the one or more polynomial coefficient indices.

Aspect 8: The method of Aspect 7, wherein performing the binary search further comprises: determining a difference between the normalized energy and a reference point corresponding to the subinterval of the interval; or determining a difference between a centralized and scaled energy and a reference point corresponding to the subinterval of the interval, wherein the centralized and scaled energy corresponds to a square root of the first sequence length multiplying a difference between the normalized energy and the uniform energy.

Aspect 9: The method of Aspect 8, wherein utilizing the subinterval of the interval and the normalized energy further comprises: computing one or more polynomial values, each polynomial value, of the one or more polynomial values, corresponding to a respective polynomial coefficient index of the one or more polynomial coefficient indices; determining one or more multiplication factors, each multiplication factor, of the one or more multiplication factors, being based at least in part on a multiplication index being associated to a respective polynomial coefficient index of the one or more polynomial coefficient indices; and determining one or more approximation terms, each approximation term, of the one or more approximation terms, being based at least in part on a multiplication of a respective polynomial value, of the one or more polynomial values, and a respective multiplication factor, of the one or more multiplication factors.

Aspect 10: The method of any of Aspects 1-9, wherein each respective polynomial approximation is based at least in part on a plurality of polynomial coefficients and a polynomial degree, the plurality of polynomial coefficients and the polynomial degree being stored in a memory of the transmitter device.

Aspect 11: The method of Aspect 10, wherein the plurality of polynomial coefficients is stored in a lookup table.

Aspect 12: The method of any of Aspects 1-11, wherein forming the polynomial approximations of the plurality of approximation factors comprises: determining an approximation region based at least in part on the first sequence length and the first sequence energy, the approximation region being associated with the first alphabet; identifying an approximation form that corresponds to the approximation region, wherein forming the polynomial approximations of the plurality of approximation factors is based at least in part on the identifying of the approximation form.

Aspect 13: The method of any of Aspects 1-12, wherein the cumulative sequence quantity defines a cardinality of a set of all sequences over the first alphabet, each sequence, of the set of all sequences over the first alphabet, having a respective length equal to the first sequence length and a respective energy less than or equal to the first sequence energy.

Aspect 14: The method of any of Aspects 1-13, wherein obtaining the approximation of the logarithm of the cumulative sequence quantity further comprises: multiplying each polynomial approximation, of the polynomial approximations of the plurality of approximation factors, by a respective multiplicative factor, the respective multiplicative factor being based at least in part on the first sequence length; obtaining a plurality of approximation terms based at least in part on the multiplying, each approximation term, of the plurality of approximation terms, corresponds to a respective polynomial approximation of the polynomial approximations of the plurality of approximation factors; and summing the plurality of approximation terms to obtain the approximation of the logarithm of the cumulative sequence quantity.

Aspect 15: The method of any of Aspects 1-14, wherein the polynomial approximations of the plurality of approximation factors comprise at least one of: a first piecewise polynomial approximation of a saturated entropy function of a normalized energy, the saturated entropy function corresponding to a first approximation factor of the plurality of approximation factors, and the saturated entropy function being associated with the first alphabet; or a respective piecewise polynomial approximation corresponding to each of one or more additional functions, each of the one or more additional functions being a function of the normalized energy or a centralized and scaled energy.

Aspect 16: The method of any of Aspects 1-15, wherein forming the polynomial approximations of the plurality of approximation factors further comprises: removing singularities from at least one of the polynomial approximations of the plurality of approximation factors.

Aspect 17: The method of any of Aspects 1-16, wherein the logarithm, of the cumulative sequence quantity, is under a base of 2, and the performing of the exponentiation operation is under a base of 2.

Aspect 18: The method of any of Aspects 1-17, wherein at least one of: the probabilistic shaping scheme is associated with the second alphabet and the second sequence length; the second alphabet size is greater than 1; or the second alphabet comprises a plurality of amplitude symbols.

Aspect 19: The method of any of Aspects 1-18, wherein: the first alphabet is a subset of or equal to the second alphabet; the first sequence length is less than or equal to the second sequence length; and the first sequence energy is less than or equal to the energy threshold.

Aspect 20: The method of any of Aspects 1-19, wherein at least one of: the second sequence length is a power of 2; or the first sequence length is a power of 2.

Aspect 21: The method of any of Aspects 1-20, wherein the probabilistic shaping scheme and the transmitting are performed by a user equipment (UE).

Aspect 22: The method of any of Aspects 1-21, wherein the probabilistic shaping scheme and the transmitting are performed by a network node.

Aspect 23: An apparatus for wireless communication at a device, comprising a processor; memory coupled with the processor; and instructions stored in the memory and executable by the processor to cause the apparatus to perform the method of one or more of Aspects 1-22.

Aspect 24: A device for wireless communication, comprising a memory and one or more processors coupled to the memory, the one or more processors configured to perform the method of one or more of Aspects 1-22.

Aspect 25: An apparatus for wireless communication, comprising at least one means for performing the method of one or more of Aspects 1-22.

Aspect 26: A non-transitory computer-readable medium storing code for wireless communication, the code comprising instructions executable by a processor to perform the method of one or more of Aspects 1-22.

Aspect 27: A non-transitory computer-readable medium storing a set of instructions for wireless communication, the set of instructions comprising one or more instructions that, when executed by one or more processors of a device, cause the device to perform the method of one or more of Aspects 1-22.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

1. An apparatus for wireless communication at a transmitter device, comprising:
a memory; and
one or more processors, coupled to the memory, configured to:
obtain a plurality of information bits for a probabilistic shaping scheme, the probabilistic shaping scheme being associated with an energy threshold;
form, as part of the probabilistic shaping scheme, polynomial approximations of a plurality of approximation factors;
obtain, using the polynomial approximations of the plurality of approximation factors, an approximation of a logarithm of a cumulative sequence quantity, the logarithm of the cumulative sequence quantity being associated with a first alphabet having a first alphabet size, a first sequence length, and a first sequence energy;
perform an exponentiation operation on the approximation of the logarithm of the cumulative sequence quantity, thereby obtaining an approximation of the cumulative sequence quantity;
encode, as part of the probabilistic shaping scheme, the plurality of information bits to obtain a symbol sequence based at least in part on the approximation of the cumulative sequence quantity, the symbol sequence having a length equal to a second sequence length and an energy less than or equal to the energy threshold, wherein each symbol of the symbol sequence belongs to a second alphabet having a second alphabet size; and
transmit a message to one or more receiver devices based at least in part on the symbol sequence.

2. The apparatus of claim 1, wherein the one or more processors, to form the polynomial approximations of the plurality of approximation factors, are configured to:
determine a normalized energy corresponding to a ratio between the first sequence energy and the first sequence length;
obtain a uniform energy, the uniform energy being associated with the first alphabet;
obtain a subinterval of an interval based at least in part on the normalized energy; and
utilize the subinterval of the interval and the normalized energy to form at least one of the polynomial approximations of the plurality of approximation factors.

3. The apparatus of claim 2, wherein at least one of:
the interval is associated with the first alphabet;
the interval comprises a plurality of subintervals, and the interval corresponds to a disjoint union of the plurality of subintervals; or
each subinterval, of the plurality of subintervals of the interval, corresponds to a respective left subinterval boundary of a plurality of left subinterval boundaries.

4. The apparatus of claim 3, wherein each subinterval, of the plurality of subintervals of the interval, is associated with one or more respective approximation region indices, each one of the one or more respective approximation region indices being associated with at least one of:
a respective reference point of a plurality of reference points,
a respective additional indices, or
one or more respective polynomial coefficient indices, each polynomial coefficient index, of the one or more respective polynomial coefficient indices, being associated with a respective multiplication index of a plurality of multiplication indices and a respective type indicator of a plurality of type indicators.

5. The apparatus of claim 4, wherein at least one of:
one or more reference points of the plurality of reference points correspond to dyadic numbers;
one or more left subinterval boundaries of the plurality of subintervals of the interval correspond to dyadic numbers;
one or more reference points of the plurality of reference points coincide with one or more respective left subinterval boundaries of the plurality of left subinterval boundaries; or
a total number of reference points of the plurality of reference points is smaller than a total number of left subinterval boundaries of the plurality of subintervals of the interval.

6. The apparatus of claim 4, wherein:
the plurality of left subinterval boundaries is stored as a binary tree structure having a root node, a plurality of internal nodes, and a plurality of leaf nodes;
each internal node, of the plurality of internal nodes, stores one key that corresponds to a respective left subinterval boundary; and
each leaf node, of the plurality of leaf nodes, stores one subinterval index that corresponds to a respective subinterval of the plurality of subintervals of the interval.

7. The apparatus of claim 6, wherein the one or more processors, to obtain the subinterval of the interval, are configured to:
perform a binary search by traversing a path of the binary tree structure from the root node to a leaf node of the plurality of leaf nodes, wherein the leaf node, of the plurality of leaf nodes, stores a subinterval index that corresponds to the subinterval of the interval;
identify the subinterval of the interval based at least in part on the subinterval index;
determine an approximation region index based at least in part on the first sequence length and the identifying of the subinterval of the interval;
identify one or more polynomial coefficient indices, the one or more polynomial coefficient indices being associated with the approximation region index;
identify a respective multiplication index for each polynomial coefficient index of the one or more polynomial coefficient indices; and
identify a respective type indicator for each polynomial coefficient index of the one or more polynomial coefficient indices.

8. The apparatus of claim 7, wherein the one or more processors, to perform the binary search, are configured to:
determine a difference between the normalized energy and a reference point corresponding to the subinterval of the interval; or
determine a difference between a centralized and scaled energy and a reference point corresponding to the subinterval of the interval, wherein the centralized and scaled energy corresponds to a square root of the first sequence length multiplying a difference between the normalized energy and the uniform energy.

9. The apparatus of claim 8, wherein the one or more processors, to utilize the subinterval of the interval and the normalized energy, are configured to:
compute one or more polynomial values, each polynomial value, of the one or more polynomial values, corresponding to a respective polynomial coefficient index of the one or more polynomial coefficient indices;
determine one or more multiplication factors, each multiplication factor, of the one or more multiplication factors, being based at least in part on a multiplication index being associated to a respective polynomial coefficient index of the one or more polynomial coefficient indices; and
determine one or more approximation terms, each approximation term, of the one or more approximation terms, being based at least in part on a multiplication of a respective polynomial value, of the one or more polynomial values, and a respective multiplication factor, of the one or more multiplication factors.

10. The apparatus of claim 1, wherein each respective polynomial approximation is based at least in part on a plurality of polynomial coefficients and a polynomial degree, the plurality of polynomial coefficients and the polynomial degree being stored in a memory of the transmitter device.

11. (canceled)

12. The apparatus of claim 1, wherein the one or more processors, to form the polynomial approximations of the plurality of approximation factors, are configured to:
determine an approximation region based at least in part on the first sequence length and the first sequence energy, the approximation region being associated with the first alphabet; and
identify an approximation form that corresponds to the approximation region, wherein forming the polynomial approximations of the plurality of approximation factors is based at least in part on the identifying of the approximation form.

13. The apparatus of claim 1, wherein the cumulative sequence quantity defines a cardinality of a set of all sequences over the first alphabet, each sequence, of the set of all sequences over the first alphabet, having a respective length equal to the first sequence length and a respective energy less than or equal to the first sequence energy.

14. The apparatus of claim 1, wherein the one or more processors, to obtain the approximation of the logarithm of the cumulative sequence quantity, are configured to:
multiply each polynomial approximation, of the polynomial approximations of the plurality of approximation factors, by a respective multiplicative factor, the respective multiplicative factor being based at least in part on the first sequence length;
obtain a plurality of approximation terms based at least in part on the multiplying, each approximation term, of the plurality of approximation terms, corresponds to a respective polynomial approximation of the polynomial approximations of the plurality of approximation factors; and
sum the plurality of approximation terms to obtain the approximation of the logarithm of the cumulative sequence quantity.

15. The apparatus of claim 1, wherein the polynomial approximations of the plurality of approximation factors comprise at least one of:
a first piecewise polynomial approximation of a saturated entropy function of a normalized energy, the saturated entropy function corresponding to a first approximation factor of the plurality of approximation factors, and the saturated entropy function being associated with the first alphabet; or
a respective piecewise polynomial approximation corresponding to each of one or more additional functions, each of the one or more additional functions being a function of the normalized energy or a centralized and scaled energy.

16. The apparatus of claim 1, wherein the one or more processors, to form the polynomial approximations of the plurality of approximation factors, are configured to:
remove singularities from at least one of the polynomial approximations of the plurality of approximation factors.

17. (canceled)

18. The apparatus of claim 1, wherein at least one of:
the probabilistic shaping scheme is associated with the second alphabet and the second sequence length;
the second alphabet size is greater than 1; or
the second alphabet comprises a plurality of amplitude symbols.

19. The apparatus of claim 1, wherein:
the first alphabet is a subset of or equal to the second alphabet;
the first sequence length is less than or equal to the second sequence length; and
the first sequence energy is less than or equal to the energy threshold.

20. The apparatus of claim 1, wherein at least one of:
the second sequence length is a power of 2; or
the first sequence length is a power of 2.

21. (canceled)

22. The apparatus of claim 1, wherein the probabilistic shaping scheme and a transmission of the message are performed by a network node.

23-46. (canceled)
